(19) United States
(12) Patent Application Publication
(10) Pub. No.: US 2007/0057254 A1
(43) Pub. Date: Mar. 15, 2007

(54) Organic semiconductor film, organic semiconductor element and organic electroluminescence element

(75) Inventor: Masayuki Mishima, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/518,119

(22) Filed: Sep. 11, 2006

(30) Foreign Application Priority Data
Sep. 14, 2005 (JP) 2005-267381

(51) Int. Cl. H01L 51/00; H01L 51/54

(52) U.S. Cl. 257/40; 257/E51.026; 428/917; 313/504; 313/506

(57) ABSTRACT

The present invention provides an organic semiconductor thin film sandwiched between a pair of electrodes, wherein a composition constituting this thin film does not substantially have a localized level between the highest occupied molecular orbit (HOMO) and the lowest unoccupied molecular orbit (LUMO) of the composition.

### CROSS-REFERENCE TO RELATED APPLICATION

This application claims priority under 35 USC 119 from Japanese Patent Application No. 2005-267381, the disclosures of which are incorporated by reference herein.

### BACKGROUND OF THE INVENTION

1. Field of the Invention

This invention relates to an organic semiconductor film, an organic semiconductor element and an organic electroluminescence element.

2. Description of the Related Art

Organic semiconductor elements have developed remarkably in recent years, certain of which have been put to practical use including, for example, electrophotographic photosensitive elements used in copying machines or printers as light-electricity converting elements, and organic electroluminescence elements mounted in certain small-sized displays of cellular phones or digital cameras, as electricity-light conversion elements. Furthermore, in recent years, active development of organic TFT elements, which are transistor devices using monocrystal pentacene has been conducted. However, further improvement of the organic electroluminescence elements is desired in terms of life span and light emitting efficiency. For organic TFT elements, it is desired that problems such as the fact that the threshold voltage cannot be adequately controlled, the response rate is slow, the dark current is large, and other problems are resolved.

So far, from various viewpoints, attempts have been made to improve the light emitting efficiency and the response rate and to decrease noise caused by the dark current.

As one of the efforts, a method of adopting a precise purification process such as a fractional sublimation process has been proposed on the basis that impurities contained in the organic compound layer make the response rate small and that the impurities cause the dark current (see Synthetic Metals, vol. 111-112, p. 277, 2000).

It has also been known for some time that water content or oxygen deteriorates the performances of an organic semiconductor element in the same manner as the impurities. It is assumed that a reaction product made from an organic material contained in the organic compound layer and water or oxygen deteriorates the performances. Thus, a method of making the element into a film form in an environment where the concentration of oxygen is 1 ppm or less and then sealing the element after the formation of the film so as not to bring the element into contact with external air has been proposed (see Synthetic Metals, vol. 122, p. 49, 2001).

The above-mentioned improvements are made by these methods. However, the above-mentioned improvements by these methods are far from reacting the levels required for practical use. Thus, further improvements are desired.

### SUMMARY OF THE INVENTION

The present invention has been made in view of the above circumstances and provides organic semiconductor Film, organic semiconductor element and organic electroluminescence element.

A first aspect of the present invention provides an organic semiconductor thin film comprising at least one organic compound of a hole transporting material and/or an electron transporting material, wherein a localized level is not substantially present between a highest occupied molecular orbit (HOMO) and a lowest unoccupied molecular orbit (LUMO) of the film.

A second aspect of the present invention provides an organic semiconductor thin film comprising at least one organic compound of a hole transporting material and/or an electron transporting material, the film substantially not having any current peak observed in a temperature range of measurement temperatures of 100 to 200 K in a measurement based on a thermally stimulated current measuring method.

### BRIEF DESCRIPTION OF THE DRAWINGS

FIG. 1 is a conception diagram of energy levels of an ITO/NPD/Al organic semiconductor thin film.

FIGS. 2-a to 2-c are each a conception diagram of a thermally stimulated current (TSC) method.

FIG. 3 is a graph showing a TCS curve of an organic semiconductor thin film madeof NPD alone.

FIG. 4 is a graph showing a TCS curve of an organic semiconductor thin film made of NPD and compound (1) wherein a blend ratio by mass of the former to the latter is 75/25.

FIG. 5 is a graph showing a TCS curve of an organic semiconductor thin film made of CBP and compound (1) wherein a blend ratio by mass of the former to the latter is 50/50.

FIG. 6 is a graph showing a TCS curve of an organic semiconductor thin film made of CBP alone.

FIG. 7 is a graph showing a TCS curve of an organic semiconductor thin film made of electron transporting material (59) and compound (1) wherein a blend ratio by mass of the former to the latter is 40/60.

FIG. 8 is a graph showing a TCS curve of an organic semiconductor thin film made of electron transporting material (59) alone.

FIG. 9 is a graph showing a TCS curve of an organic semiconductor thin film made of NPD and compound (19) wherein a blend ratio by mass of the former to the latter is 75/25.

FIG. 10 is a graph showing a TCS curve of an organic semiconductor thin film made of NPD and compound (44) wherein a blend ratio by mass of the former to the latter is 75/25.

### DETAILED DESCRIPTION OF THE INVENTION

1. Organic Semiconductor Thin Film

The organic semiconductor thin film in the invention is an organic thin film which is sandwiched between a pair of electrodes and makes it possible that holes and/or electrons are shifted in this film by applying an electric field to the electrodes across the electrodes so as to cause electric current to flow. The film is preferably a film exhibiting a charge mobility of 10⁻⁷ cm²/Vs or more at an applied voltage of 10⁶ V/cm⁻¹.

The organic semiconductor thin film of the invention is an organic semiconductor thin film comprising at least one organic compound of a hole transporting material and/or an electron transporting material. The thickness of the organic thin film is preferably 1 nm or more to 1 mm or less, more preferably 1 nm or more to 100 μm or less. If the thickness is smaller than this lower limit, the organic thin film hardly becomes a uniform film. If the thickness is larger than this upper limit, the movement of electrons or holes becomes very slow.

1) Hole Transporting Material

The hole transporting material is not particularly limited if the material has a function of transporting holes. Any one of a low molecular weight hole transporting material and a high molecular weight hole transporting material can be used. Specific examples of the material include the following:

A carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydorazone derivative, a stylbene derivative, a silazane derivative, an aromatic tertiary amine compound, a styrylamine compound, an aromatic dimethylidene compound, a porphyrin compound, a polysilane compound, a poly(N-vinylcarbazole) derivative, other electroconductive polymer/oligomers such as an aniline copolymer, a thiophene oligomer and polythiophene, and polymeric compounds such as a polythiophene derivative, a polyphenylene derivative, a polyphenylenevinylene derivative and a polyfluorene derivative.

These may be used alone or in combination of two or more kinds thereof.

2) Electron Transporting Material

The electron transporting material is not particularly limited if the material has a function of transporting electrons, and may be an ordinary electron transporting material. Examples thereof include the following:

a triazole derivative, an oxazole derivative, an oxadiazole derivative, a fluorenone derivative, an anthraquinodimethane derivative, an anthrone derivative, a diphenylquinone derivative, a thiopyranedioxide derivative, a carbodiimide derivative, a fluorenylidenemethane derivative, a distyrylpyrazine derivative, heterocyclic tetracarboxylic anhydrides such as naphthaleneperylene, various metal complexes, typical examples of which include metal complexes of a phthalocyanine derivative or 8-quinolinol derivative, metal phthalocyanine, and metal complexes each having, as a ligand thereof, benzooxazole or benzothiazole, electroconductive polymers/oligomers such as an aniline copolymer, a thiophene oligomer and polythiophene, and polymeric compounds such as a polythiophene derivative, a polyphenylene derivative, a polyphenylenevinylene derivative and a polyfluorene derivative. These may be used alone or in combination of two or more kinds thereof.

3) Control of Localized Levels

The organic semiconductor thin film of the invention is an organic semiconductor thin film comprising at least one organic compound of a hole transporting material and/or an electron transporting material wherein a localized level is not substantially present between a highest occupied molecular orbit (HOMO) and a lowest unoccupied molecular orbit (LUMO) of the film. Another aspect of the organic semiconductor thin film of the invention is an organic semiconductor thin film comprising at least one organic compound of a hole transporting material and/or an electron transporting material, the film substantially not having any current peak observed in a temperature range of measurement temperatures of 100 to 200 K in a measurement based on a thermally stimulated current measuring method. The wording “substantially not having any current peak observed in a temperature range of measurement temperatures of 100 to 200 K in a measurement based on a thermally stimulated current measuring method” means that there is not any larger peak than the TSC detection limit in the range of 100 K (0.14 eV) to 200 K (0.33 eV) in thermally stimulated current measuring method (TSC) measurement described below. In other words, it means that there is no observation of a current value more than 1E-14A/4mm² in the TSC measurement.

The method for removing any localized level in the invention is a method of canceling intermolecular overlap based on intermolecular interaction of material molecules which constitute the organic semiconductor thin film. The method for canceling this intermolecular interaction in the invention is preferably a method of incorporating, into the organic semiconductor thin film, an organic compound wherein the difference (Eg) between the HOMO and the LUMO is 4.0 kV or more. This organic compound used in the invention is preferably an aromatic hydrocarbon compound.

4) Aromatic Hydrocarbon Compound

In the invention, the aromatic hydrocarbon compound is preferably an aromatic hydrocarbon compound represented by the formula (1) or (2).
L-(Ar)ₘ Formula (1)

In Formula (1), Ar is a group represented by the following Formula (2), L is a phenyl group having a valence of 3 or more, and m is an integer of 3 or more.

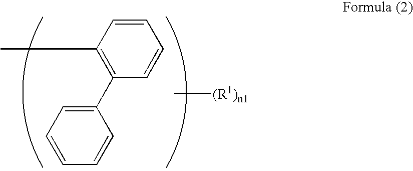

R¹ is a substituent which can be substituted with benzene ring, and when a plurality of R¹s are present, respective R¹s may either be the same as or different from each other. n1 is an integer from 0 to 9.

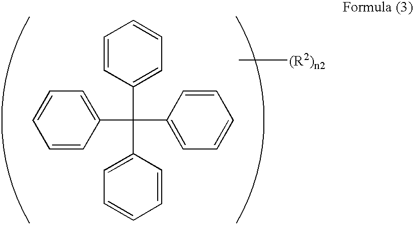

In Formula (3), R² is a substituent which can be substituted with benzene ring, and when a plurality of R²s are present, respective R² may either be the same as or different from each other. n2 is an integer from 0 to 20.

First, Formula (1) will be explained in detail.

L included in Formula (1) is a phenyl group having a valence of 3 or more.

Ar included in Formula (1) is a group represented by Formula (2), and m is an integer of 3 or more.

m is preferably 3 or more and 6 or less, and it is further preferably 3 or 4.

Next, the group represented by Formula (2) will be explained.

R¹ included in Formula (2) is a substituent which can be substituted with benzene ring.

Examples of the substituent which can be substituted with benzene ring include an alkyl group (preferably having 1 to 30 carbon atoms, more preferably having 1 to 20 carbon atoms, and particularly preferably having 1 to 10 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, a cyclohexyl group and the like), an alkenyl group (preferably having 2 to 30 carbon atoms, more preferably having 2 to 20 carbon atoms, and particularly preferably having 2 to 10 carbon atoms, and examples thereof include a vinyl group, an allyl group, a 2-butenyl group, a 3-pentenyl group, and the like), an alkynyl group (preferably having 2 to 30 carbon atoms, more preferably having 2 to 20 carbon atoms, and particularly preferably having 2 to 10 carbon atoms, and examples thereof include a propalgyl group, a 3-pentinyl group and the like), an aryl group (preferably having 6 to 30 carbon atoms, more preferably having 6 to 20 carbon atoms, and particularly preferably having 6 to 12 carbon atoms, and examples thereof include a phenyl group, a p-methyl phenyl group, a naphthyl group, an anthranyl group and the like), an amino group (preferably having 0 to 30 carbon atoms, more preferably having 0 to 20 carbon atoms, and particularly preferably having 0 to 10 carbon atoms, and examples thereof include an amino group, a methyl amino group, a dimethyl amino group, a diethyl amino group, a dibenzyl amino group, a diphenyl amino group, a ditolyl amino group and the like), an alkoxy group (preferably having 1 to 30 carbon atoms, more preferably having 1 to 20 carbon atoms, and particularly preferably having 1 to 10 carbon atoms, and examples thereof include a methoxy group, an ethoxy group, a butoxy group, a 2-ethyl hexyloxy group and the like), an aryloxy group (preferably having 6 to 30 carbon atoms, more preferably having 6 to 20 carbon atoms, and particularly preferably having 6 to 12 carbon atoms, and examples thereof include a phenyloxy group, a 1-naphtyloxy group, a 2-naphthyloxy group and the like),

a heteroaryloxy group (preferably having 1 to 30 carbon atoms, more preferably having 1 to 20 carbon atoms, and particularly preferably having 1 to 12 carbon atoms, and examples thereof include a pyridyloxy group, a pyradyloxy group, a pyrymidyloxy group, a quinolyloxy group and the like), an acyl group (preferably having 1 to 30 carbon atoms, more preferably having 1 to 20 carbon atoms, and particularly preferably having 1 to 12 carbon atoms, and examples thereof include an acetyl group, a benzoyl group, a formyl group, a pivaloyl group and the like), an alkoxy carbonyl group (preferably having 2 to 30 carbon atoms, more preferably having 2 to 20 carbon atoms, and particularly preferably having 2 to 12 carbon atoms, and examples thereof include a methoxy carbonyl group, an ethoxy carbonyl group and the like), an aryloxy carbonyl group (preferably having 7 to 30 carbon atoms, more preferably having 7 to 20 carbon atoms, and particularly preferably having 7 to 12 carbon atoms, and examples thereof include a phenyloxy carbonyl group and the like), an acyloxy group (preferably having 2 to 30 carbon atoms, more preferably having 2 to 20 carbon atoms, and particularly preferably having 2 to 10 carbon atoms, and examples thereof include an acetoxy group, a benzoyloxy group and the like), an acyl amino group (preferably having 2 to 30 carbon atoms, more preferably having 2 to 20 carbon atoms, and particularly preferably having 2 to 10 carbon atoms, and examples thereof include an acetyl amino group, a benzoyl amino group and the like), an alkoxy carbonyl amino group (preferably having 2 to 30 carbon atoms, more preferably having 2 to 20 carbon atoms, and particularly preferably having 2 to 12 carbon atoms, and examples thereof include a methoxy carbonyl amino group and the like), an aryloxy carbonyl amino group (preferably having 7 to 30 carbon atoms, more preferably having 7 to 20 carbon atoms, and particularly preferably having 7 to 12 carbon atoms, and examples thereof include a phenyloxy carbonyl amino group and the like ), a sulfonyl amino group (preferably having 1 to 30 carbon atoms, more preferably having 1 to 20 carbon atoms, and particularly preferably having 1 to 12 carbon atoms, and examples thereof include a methane sulfonyl amino group, a benzene sulfonyl amino group and the like), a sulfamoyl group (preferably having 0 to 30 carbon atoms, more preferably having 0 to 20 carbon atoms, and particularly preferably having 0 to 12 carbon atoms, and examples thereof include a sulfamoyl group, a methyl sulfamoyl group, a dimethyl sulfamoyl group, a phenyl sulfamoyl group and the like),

a carbamoyl group (preferably having 1 to 30 carbon atoms, more preferably having 1 to 20 carbon atoms, and particularly preferably having 1 to 12 carbon atoms, and examples thereof include a carbamoyl group, a methyl carbamoyl group, a diethyl carbamoyl group, a phenyl carbamoyl group and the like), an alkyl thio group (preferably having 1 to 30 carbon atoms, more preferably having 1 to 20 carbon atoms, and particularly preferably having 1 to 12 carbon atoms, and examples thereof include an a methyl thio group, an ethyl thio group and the like), an aryl thio group (preferably having 6 to 30 carbon atoms, more preferably having 6 to 20 carbon atoms, and particularly preferably having 6 to 12 carbon atoms, and examples thereof include a phenyl thio group and the like), a heteroaryl thio group (preferably having 1 to 30 carbon atoms, more preferably having 1 to 20 carbon atoms, and particularly preferably having 1 to 12 carbon atoms, and examples thereof include a pyridyl thio group, a 2-benzimizolyl thio group, a 2-benzoxazoyl thio group, a 2-benzthiazolyl thio group and the like), a sulfonyl group (preferably having 1 to 30 carbon atoms, more preferably having 1 to 20 carbon atoms, and particularly preferably having 1 to 12 carbon atoms, and examples thereof include a mecyl group, a tocyl group and the like), a sulfinyl group (preferably having 1 to 30 carbon atoms, more preferably having 1 to 20 carbon atoms, and particularly preferably having 1 to 12 carbon atoms, and examples thereof include a methane sulfinyl group, a benzene sulfinyl group and the like), a ureido group (preferably having 1 to 30 carbon atoms, more preferably having 1 to 20 carbon atoms, and particularly preferably having 1 to 12 carbon atoms, and examples thereof include a ureido group, a methyl ureido group, a phenyl ureido group and the like), an amide phosphate group (preferably having 1 to 30 carbon atoms, more preferably having 1 to 20 carbon atoms, and particularly preferably having 1 to 12 carbon atoms, and examples thereof include a diethyl amide phosphate group, a phenyl amide phosphate group and the like), a hydroxyl group, a mercapto group, a halogen atom (for example, a fluorine atom, a chlorine atom, a bromine atom, an iodine atom or the like), a cyano group, a sulfo group, a carboxyl group, a nitro group, a hydroxamic acid group, a sulfino group, a hydrodino group, an imino group, a hetero cyclic group (preferably having 1 to 30 carbon atoms, and more preferably having 1 to 12 carbon atoms; examples of a hetero atom therein include a nitrogen atom, an oxygen atom, a sulfur atom and the like; and specific examples thereof include an imidazolyl group, a pyridyl group, a quinolyl group, a furyl group, a thienyl group, a piperidyl group, a morpholyno group, a benzoxazoly group, a benzimidazoyl group, a benzthiazolyl group, a carbazolyl group, an azepynyl group and the like ), a silyl group (preferably having 3 to 40 carbon atoms, more preferably having 3 to 30 carbon atoms, and particularly preferably having 3 to 24 carbon atoms, and examples thereof include a trimethyl silyl group, a triphenyl silyl group and the like ) and the like.

When a plurality of R¹s are present, respective R¹ may either be the same as or different from each other, and they may be bonded with each other so as to form a ring. Moreover, R¹ may further have a substitutent.

Examples of the substituents included in R¹ are preferably an alkyl group, an aryl group, a heteroaryl group, more preferably an aryl group and a heteroaryl group.

n1 is an integer from 0 to 9. n1 is preferably an integer from 0 to 6, and it is further preferably 0 to 3.

Subsequently, Formula (3) will be explained.

R² in Formula (3) is a substituent which can be substituted with benzene ring. The substituent represented by R² is similar to the above-mentioned substituent represented by R¹ including the preferable embodiments, and preferable examples thereof are also similar to those of the substituent represented by R¹.

n2 is an integer from 0 to 20. The preferable range of n2 is from 0 to 10, and it is further preferably 0 to 5.

The compound examples of Formula (1) or Formula (3) will be shown below; however, the present invention is not limited thereto. 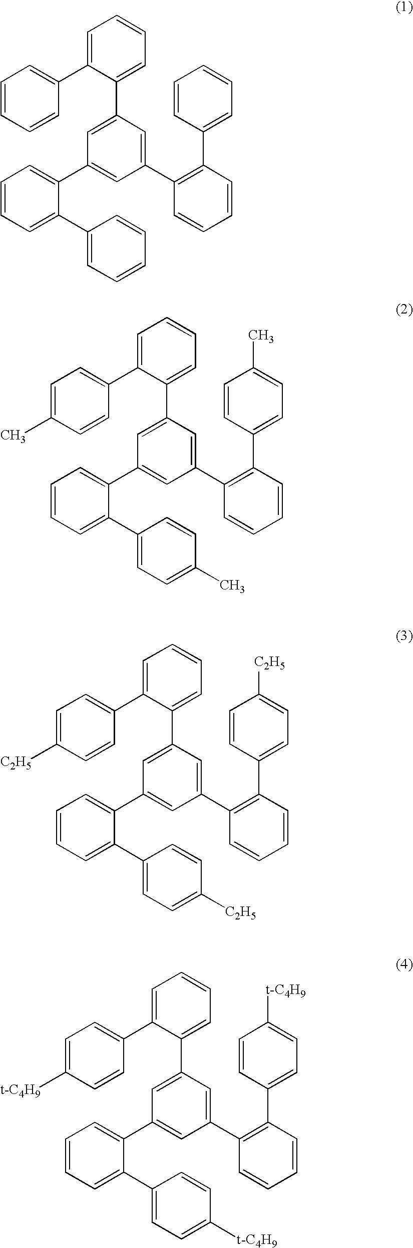 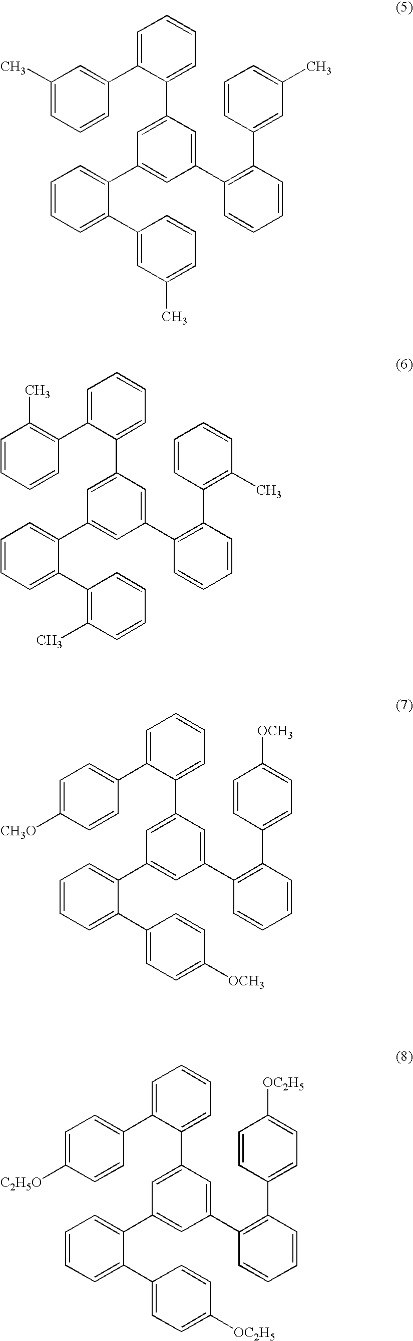 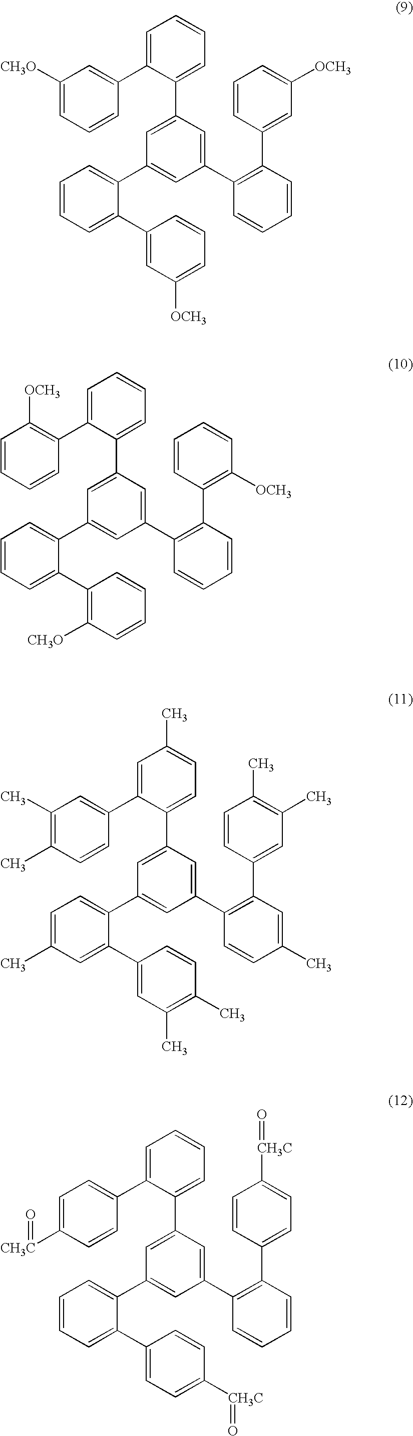 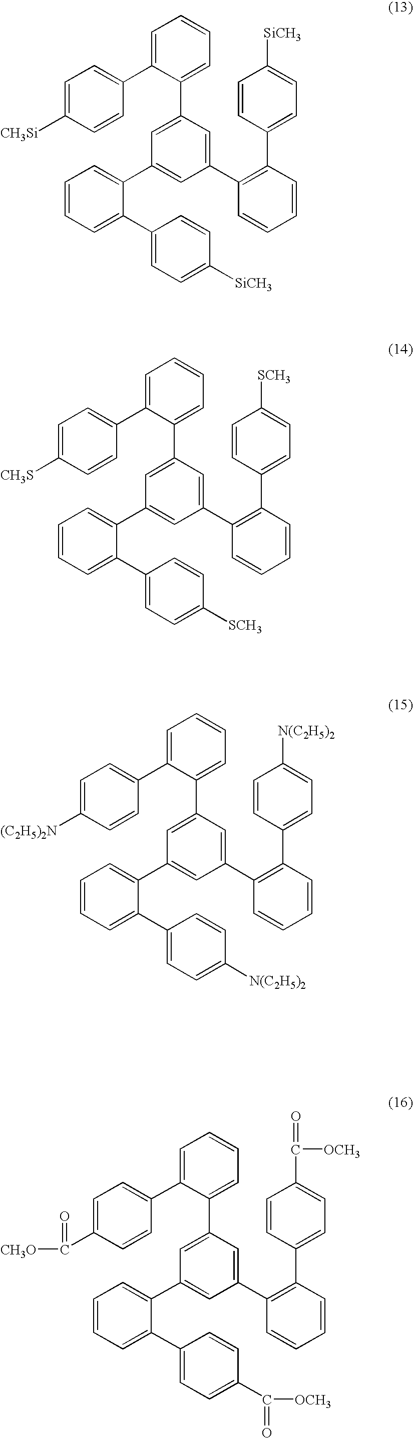 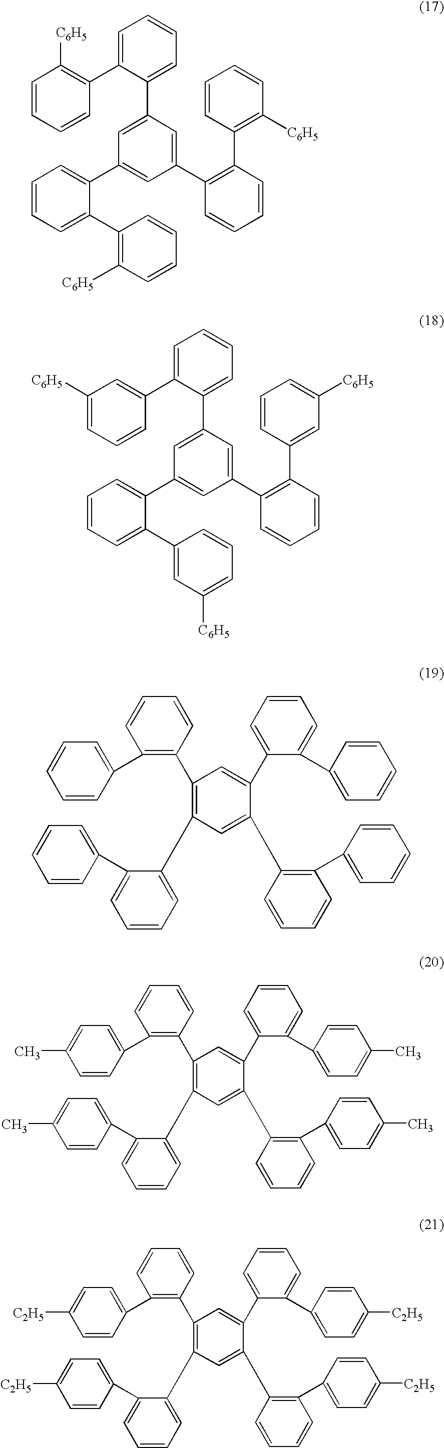 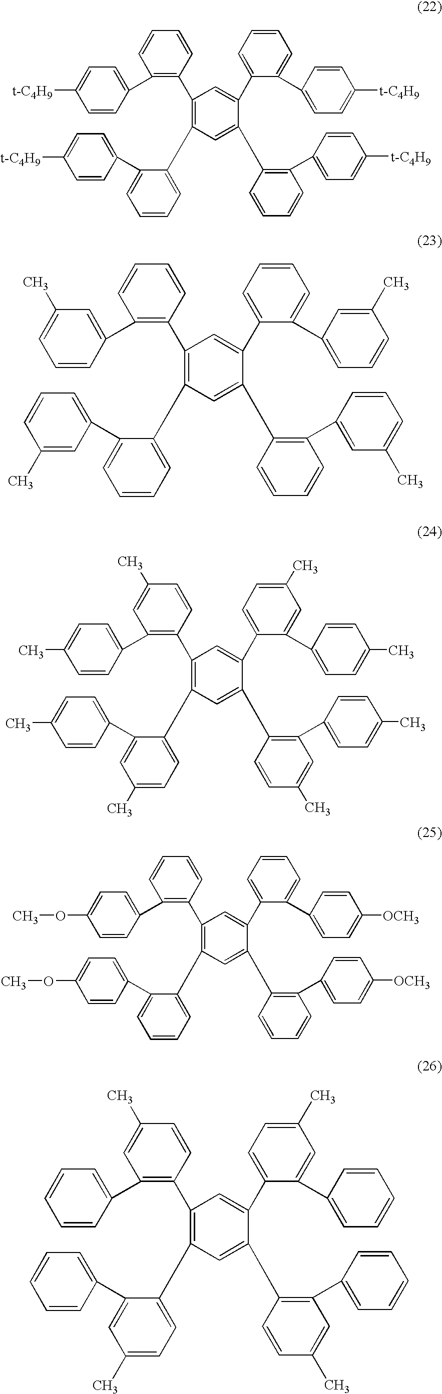 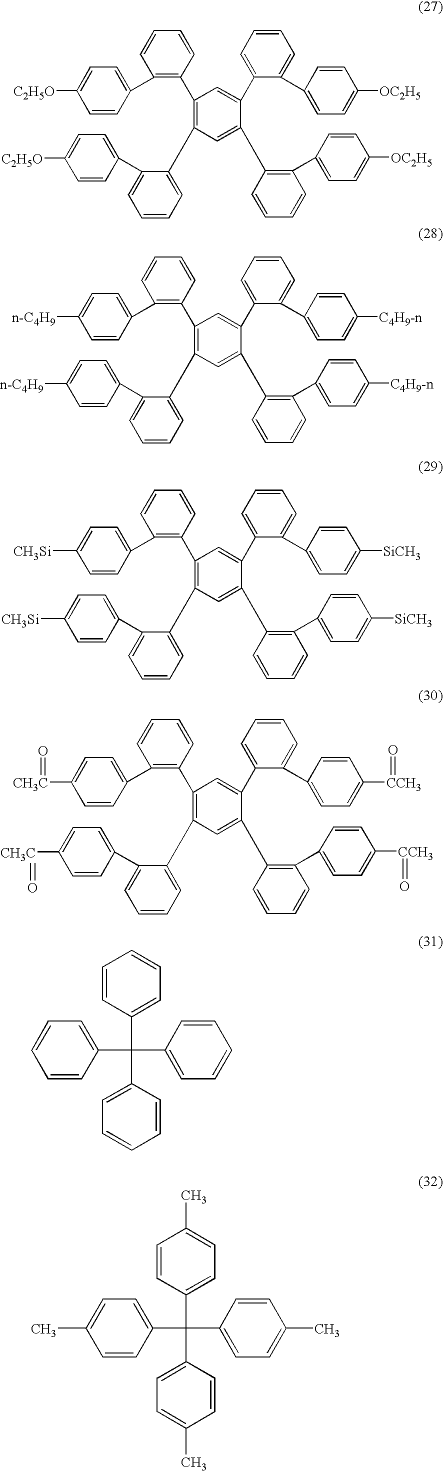 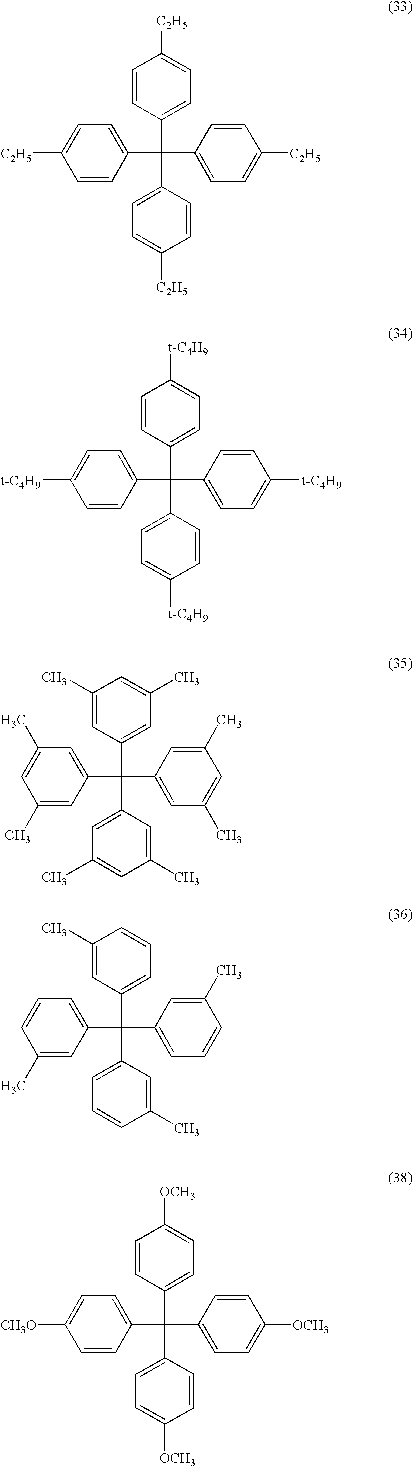 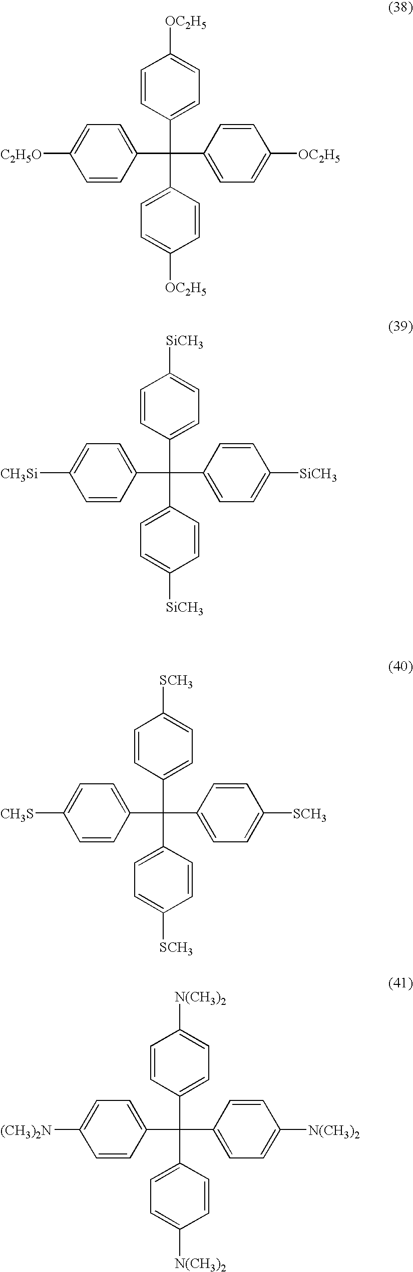 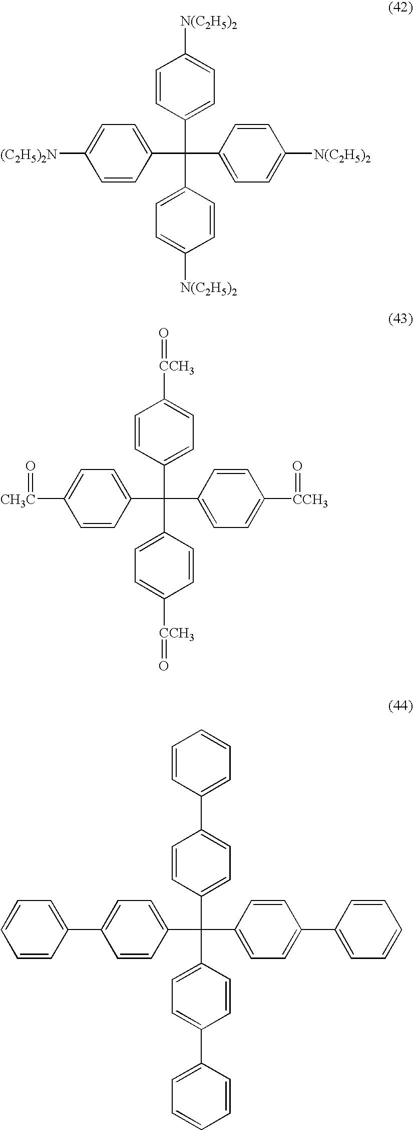 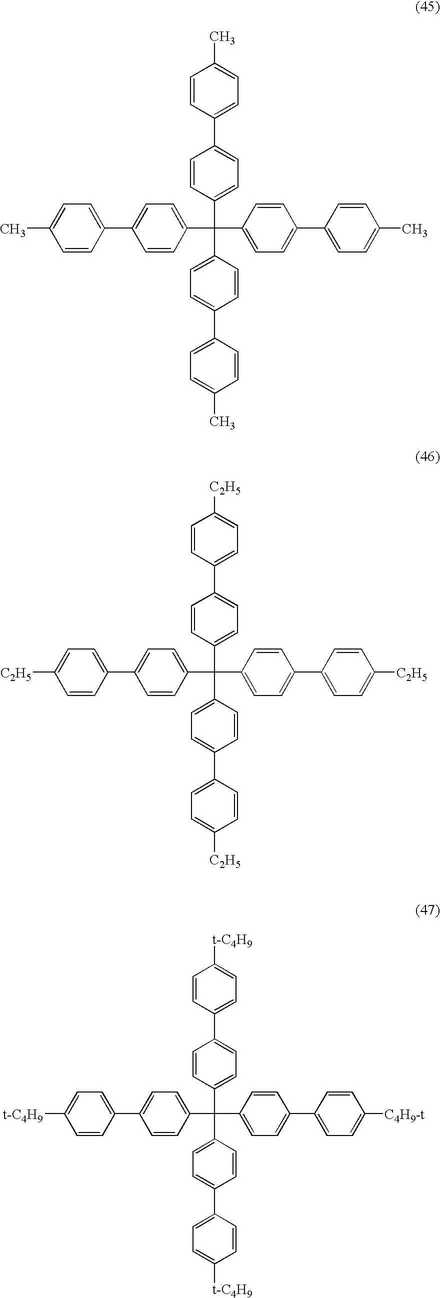 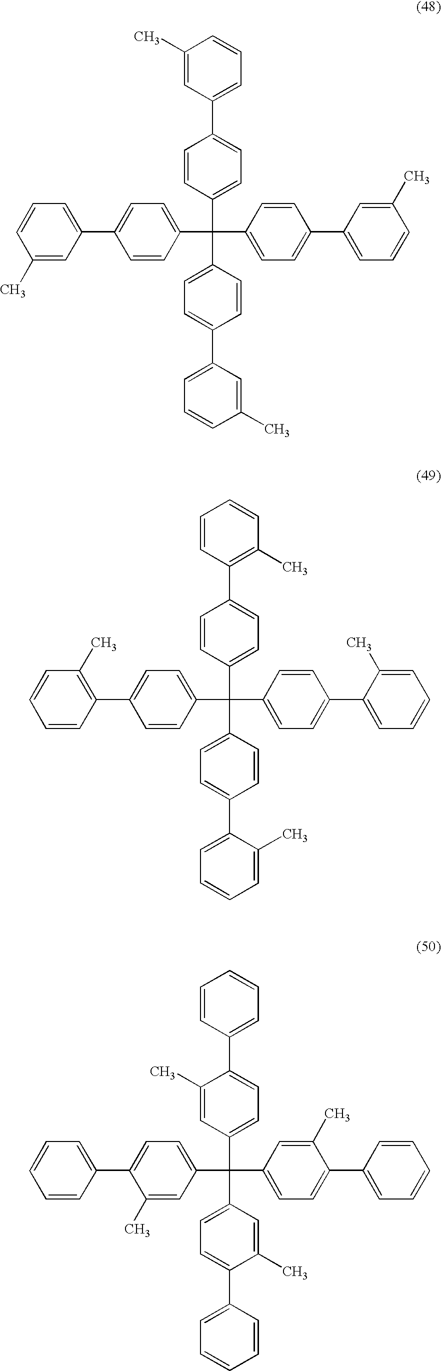 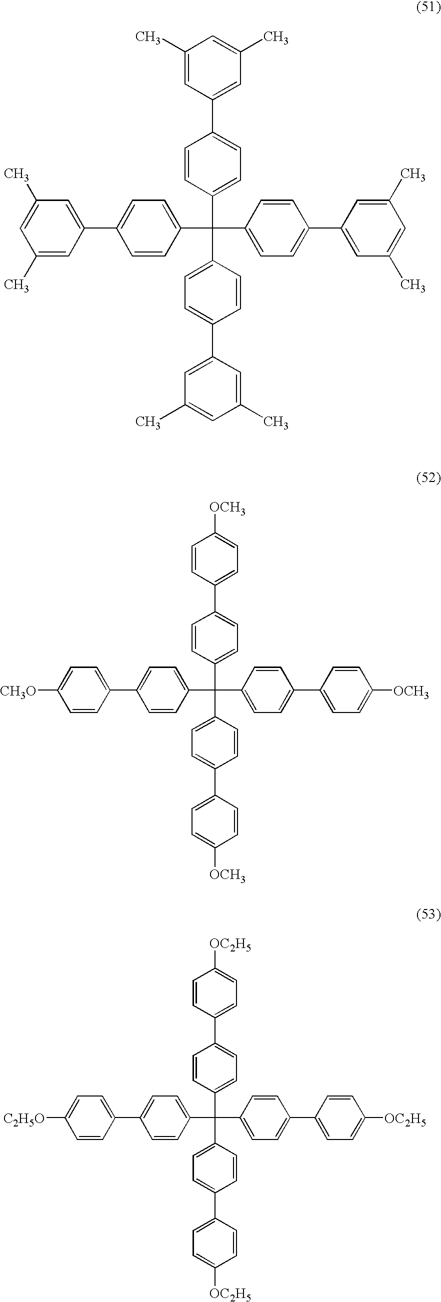 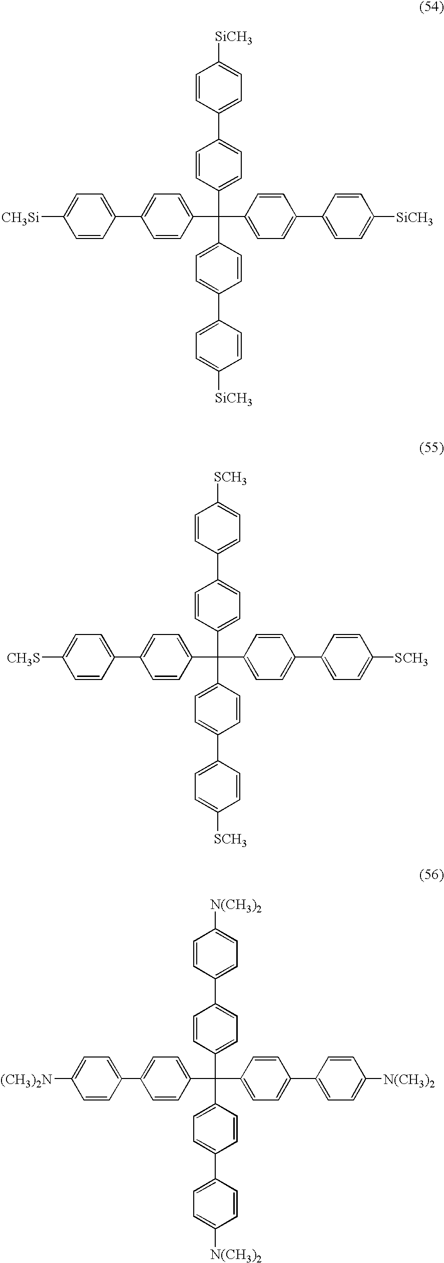 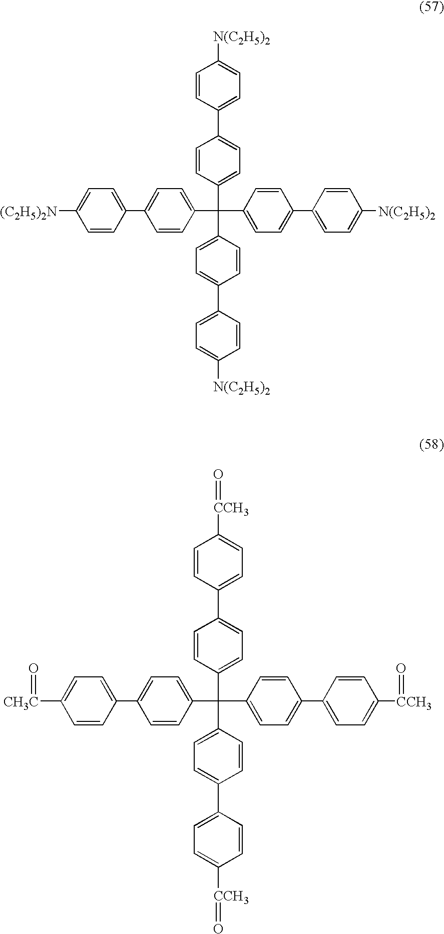
5) Structure of the Organic Semiconductor Thin Film

In the invention, the organic semiconductor thin film preferably comprises at least one of the above-mentioned hole transporting material and/or electron transporting material, and an organic compound wherein the difference (Eg) between the HOMO and the LUMO is 4.0 kV or more. The blend ratio by mass of the former to the latter is preferably 95/5 to 30/70, more preferably 95/5 to 40/60. If the ratio of the organic compound is smaller than this lower limit, the effect of removing any localized level becomes small. If the ratio of electrically inactive materials is larger than this upper limit, the charge mobility of the hole transporting material and/or the electron transporting material falls so that the semiconductor property of this film is damaged. The word “comprises” means a thin film wherein the materials (the hole transporting material, the electron transporting material, and the organic compound wherein the difference (Eg) between the HOMO and the LUMO is 4.0 kV or more) are in a state that they are mixed with each other, and/or a thin film made of the materials obtained by chemical change of the materials.

6) Method for Forming the Organic Semiconductor Thin Film

The method for forming the organic semiconductor thin film in the invention is not particularly limited if the method is a film-forming method which generates no localized level. The organic semiconductor thin film can be formed onto, for example, a glass substrate on which a thin film of an electrode made of ITO or the like is formed by any method that satisfies the above requirement. Thereafter, an electrode made of Al, Ag, Mg, Ca or the like can be formed as a counter electrode onto the organic semiconductor thin film, thereby yielding an organic semiconductor element of the invention.

<Substrate>

The substrate used is not particularly limited. Examples of the raw material of the substrate include inorganic materials such as YSZ (zirconia stabilized yttrium) and glass; and organic materials such as polyesters such as polyethylene terephthalate, polybutylene terephthalate, and polyethylene naphthalate, polystyrene, polycarbonate, polyethersulfone, polyarylate, allyl diglycol carbonate, polyimide, polycycloolefin, norbornene resin, poly(chlorotrifluoroethylene) and other synthetic resins. In the case of the organic materials, it is preferred that the organic materials are organic materials excellent in heat resistance, dimensional stability, solvent resistance, electric non-conductance, workability, low gas permeability and low hygroscopicity.

<Electrode>

The electrode used is not particularly limited, and may be transparent or opaque.

Examples of the material of the electrode include metals, alloys, metal oxides, organic electroconductive compounds, and mixtures thereof. Specific examples thereof include semiconductor metal oxides such as tin oxides doped with antimony or fluorine (ATO,FTO), tin oxide, zinc oxide, indium oxide, indium tin oxide (ITO), indium zinc oxide (IZO); metals such as gold, silver, chromium, and nickel; mixtures or laminates each made of one or more kinds of the metals and one or more kinds of the electroconductive metal oxides; inorganic electroconductive materials such as copper iodide, and copper sulfide; organic electroconductive materials such as polyaniline, polythiophene, and polypyrrole; and laminates each made of ITO and one or more kinds of these materials.

The method for forming the material of the electrode into a film is not particularly limited. Examples thereof include wet methods such as printing and coating, physical methods such as vacuum vapor deposition, sputtering and ion plating, and chemical methods such as CVD and plasma CVD. By a method selected suitably from these methods under consideration of suitability for the selected material, this material can be formed into a film on the above-mentioned substrate. In the case of selecting, for example, ITO, the film-formation can be attained by direct current or high-frequency sputtering, vacuum vapor deposition (vacuum evaporation), ion plating or the like. In the case of selecting an organic electroconductive compound as the raw material of the above-mentioned anode, the film-formation can be attained by a wet film-forming method.

The method for forming the organic thin film in the invention is not particularly limited, and the film formation can be suitably attained by any one selected from the following: dry film-forming methods such as vapor deposition and sputtering; and wet film-forming methods such as dipping, spin coating, dip coating, casting, die coating, roll coating, bar coating, and gravure coating.

<Sealing>

The organic semiconductor thin film may be affected by water content or oxygen, so as to newly generate localized levels. In order to restrain this, it is preferred in the invention that about the film-forming environment for the organic semiconductor thin film the concentration of water content and that of oxygen are low. The concentration of water content and that of oxygen are each preferably 100 ppm or less, more preferably 80 ppm or less, most preferably 50 ppm or less.

After the formation of the organic semiconductor thin film, this film can be sealed in a glove box purged with an inert gas such as nitrogen or argon in such a manner that the film will not be exposed to water content or oxygen in the air.

The organic semiconductor thin film of the invention yield as described above has no localized level to exhibit a large charge mobility and significantly excellent semiconductor characteristics.

2. Measurement of a Localized Level by a Thermal Stimulation Current Method.

Whether or not there is a localized level can be measured by a thermal stimulation current method (hereinafter abbreviated as the TSC method). The TSC method will be described hereinafter. The TSC method is a method of causing charges trapped into a localized level to be discharged by heat and estimating the depth of the localized level from the temperature at which the charges are discharged. Processes for the measurement will be described hereinafter.

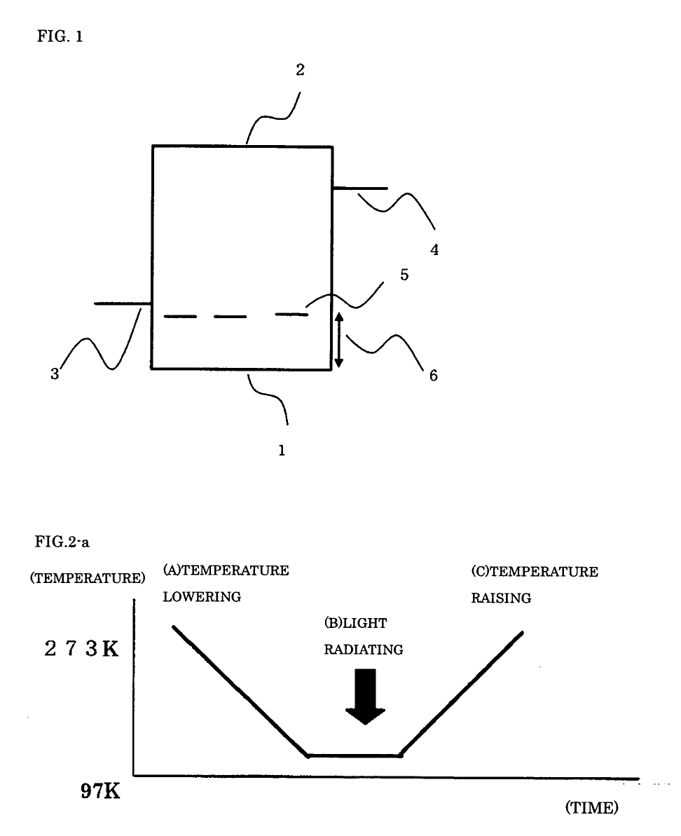

FIG. 1 shows an energy level diagram of an organic semiconductor thin film. Therein, reference number 1 represents the HOMO level of NPD (N,N′-dinaphthyl-N,N′-diphenylbenzidine); 2, the LUMO level of NPD; 3, the work function level of ITO; 4, the work function level of Al; 5, a localized level of a NPD film; and 6, the localized level energy (Ei) of NPD.

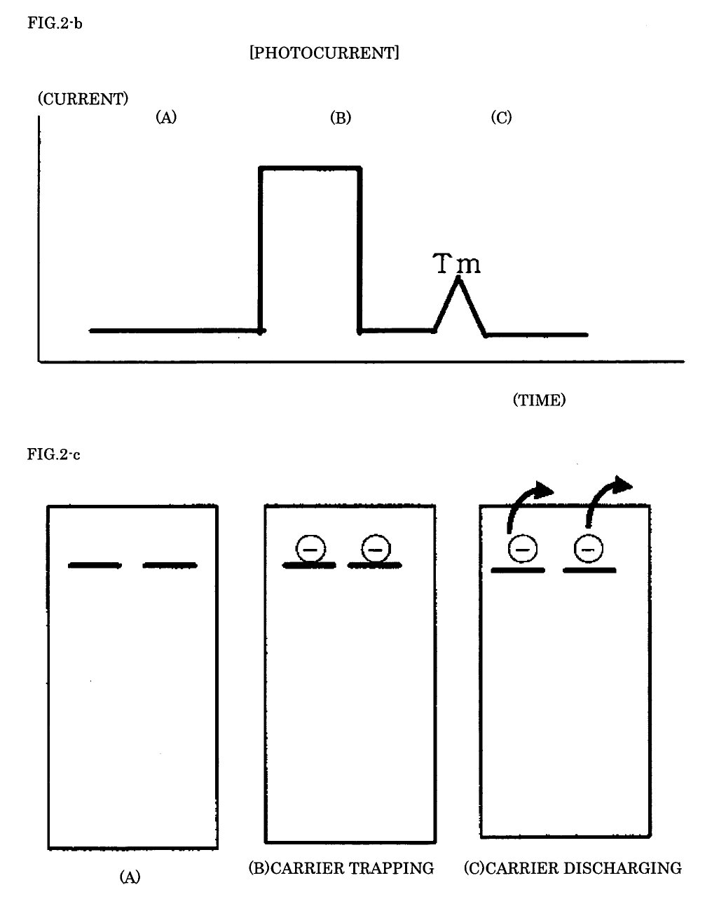

FIG. 2-a shows a time-temperature profile in each of the following processes, FIG. 2-b shows a time-current profile therein, and FIG. 2-c shows a charge accumulation/discharge profile on the localized level.

Process (A): a temperature dropping process. First, the temperature of a sample of the organic semiconductor thin film of the invention is dropped from room temperature to 93 K (−180° C.) to restrain the movement of molecules in the organic thin film, so that charges will be able to be trapped into a localized level thereof.

Process (B): a light radiating process. Light having a wavelength, which the organic semiconductor thin film sample of the invention can absorb, is radiated to the sample so as to excite the material constituting the organic semiconductor thin film. In this way, holes and electrons are dissociated to cause a photoelectric current to flow. At this time, charges are trapped into the localized level.

Process (C): a temperature raising process. The temperature of the organic semiconductor thin film sample of the invention is raised to discharge the charges from the localized level, so that a current is caused to flow. This current is measured.

At this time, the energy level (Ei) of the localized level is approximately calculated by the following equation (1):
Ei=K·Tm·In(Tm⁴/a) Equation(1)
K: constant=8.617×10⁻² [meV/K]
Tm: Peak temperature [K] of TSC
a: temperature-raising rate [K/min.]

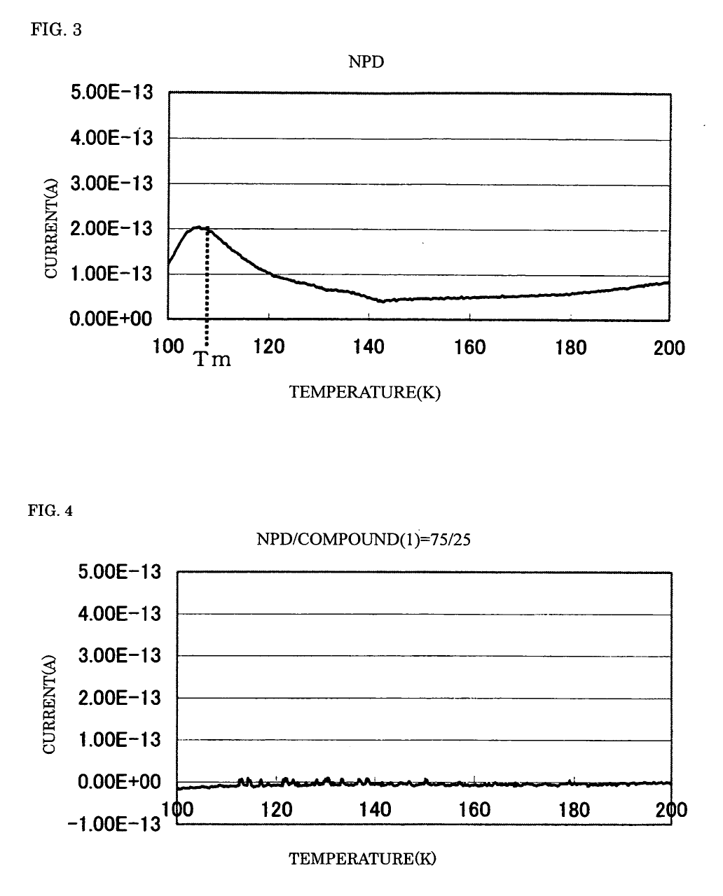

While the raised temperature is changed, the current value is measured. As a result, a relationship between the raised temperature and the current value can be represented by a TSC curve as shown in FIG. 3. When a localized level is present, a peak temperature Tm of the current can be observed. The localized level energy can be calculated therefrom on the basis of the equation (1). FIG. 3 is a TSC curve of an example wherein an organic thin film made of N,N′-dinaphthyl-N,N′-diphenylbenzidine was used. In the TSC curve of the NPD film, a peak is present at 113 K (−160° C.). It is understood from the equation (1) that this is a localized level corresponding to an energy of 0.16 eV. In other words, it is understood that a localized level is present at a level 0.16 eV higher than the HOMO level of NPD in FIG. 1.

The organic semiconductor thin film of the invention is an organic semiconductor thin film having no current peak in the temperature range of 100 K (−173° C.) to 200 K (−73° C.) according to this TSC method. The temperature 100 K corresponds to 0.14 eV. Any localized level corresponding to a temperature lower than this temperature does not substantially produce bad effects on characteristics of the semiconductor. The temperature 200 K corresponds to 0.33 eV. Peaks corresponding to temperatures higher than this temperature do not represent localized levels in many cases, but represent electrical barriers in the interface between the organic thin film and the electrode. In other words, it can be judged that any organic semiconductor thin film which does not substantially have a peak observed in the temperature range of 100 to 200 K according to the TSC method does not have any localized level that produces bad effects on the characteristics of the organic semiconductor thin film.

The measurement of the organic semiconductor thin film of the invention can be carried out by use of a thermal stimulus current meter TS-FETT manufactured by Rigaku Corp. In the TSC measurement, as a sample, the above-mentioned organic semiconductor thin film itself can be used. The measurement can be attained by making one of the pair electrodes into a transparent electrode made of ITO or the like. In the TSC measurement, the temperature-raising rate is not particularly limited. The rate is preferably 1 or more to 100 or less K/min, more preferably 2 or more to 50 or less K/min. If the rate is smaller than this lower limit, very much time is required for the measurement to result in a bad efficiency. If the rate is larger than this upper limit, the temperature of the sample does not unfavorably follow the rising temperature.

The above has described the light exciting method as the method for trapping charges into a localized level. However, in the invention, an electric field may be given between the electrodes at 93 K (−180° C.) to cause charges to flow into the organic semiconductor thin film, thereby trapping the charges into a localized level. In this case, it is necessary to give the electric field which never causes dielectric breakdown of the organic semiconductor thin film.

FIG. 4 shows an example of the TSC curve generated in the case that no localized level is present in the invention. Specifically, FIG. 4 is a TSC curve of a film wherein NPD, described above, and electrically inactive compound (1) represented by the above-mentioned general formula (1) are blended with each other at a ratio by mass of 75/25. About a film made of NPD alone shown in FIG. 3, a peak is present at 113 K. However, about the organic semiconductor thin film of the invention shown in FIG. 4, wherein the ratio by mass of NPD/compound (1)=75/25, no peak is present in the temperature range of 100 to 200 K. In short, there is no localized level.

The charge mobility of the film of NPD alone, and that of the NPD/compound (1) film are measured by the time-of-flight method (see “Polymeric Semiconductor”, written by Rei Mikawa, Kodansha 1986)). As a result, they are 2.65×10⁻³ cm²/V.second and 2.0×10⁻² cm²/V.second, respectively. Thus, it is understood that the film of the invention composed of NPD and compound (1) mixed at a ratio of 75/25, wherein no localized level is present, exhibits a high mobility and good semiconductor characteristics.

3. Application

About the organic semiconductor thin film of the invention, usage thereof is not particularly limited. The film can be used as an organic semiconductor element and/or an organic electroluminescence element. The film can be used for e.g., an organic electrophotographic photosensitive body; an organic electroluminescence element used in a display, an electron paper, a light source or the like; an organic transistor element (such as an element having an organic semiconductor layer having carrier mobility between a source electrode and a drain electrode) in an organic TFT, an organic FET or the like; an organic sensor; or the like. In particular, when the organic semiconductor thin film of the invention is used for an organic electroluminescence element, it is possible to provide, as this element, an organic electroluminescence element having a high durability and a high light-emitting efficiency.

4. Organic Electroluminescence Element

The organic electroluminescence element of the invention includes the following aspects: an electroluminescence element having at least one organic compound layer between a pair of electrodes wherein the organic compound layer is (1) an organic semiconductor thin film comprising at least one organic compound of a hole transporting material and/or an electron transporting material, wherein a localized level is not substantially present between the highest occupied molecular orbit (HOMO) and the lowest unoccupied molecular orbit (LUMO) of the film; and/or (2) an organic semiconductor thin film comprising at least one organic compound of a hole transporting material and/or an electron transporting material, the film substantially not having any current peak observed in a temperature range of measurement temperatures of 100 to 200 K in a measurement based on a thermally stimulated current measuring method. In the organic electroluminescence element of the invention, the organic semiconductor thin film may be a light emitting layer, or may function as a hole transporting layer, an electron transporting layer, a blocking layer, an electron injecting layer, a hole injecting layer, or the like. In the organic electroluminescence element of the invention may have, besides the organic semiconductor thin film, one or more functional layers known in the prior art, such as a light emitting layer, a hole transporting layer, an electron transporting layer, a blocking layer, an electron injecting layer, and a hole injecting layer.

About the organic electroluminescence element of the invention, it is preferred that its light emitting layer does not substantially have the above-mentioned localized level. It is more preferred that none of organic compound layers present in a path wherein electrons and holes move substantially have the above-mentioned localized level.

The organic electroluminescence element of the invention will be described in detail hereinafter.

1) Layer Structure

<Electrodes>

At least one of the pair electrodes of the organic electroluminescence element of the invention is a transparent electrode, and the other is a back plate. The back plate may be transparent or opaque.

<Structure of the Organic Compound Layer>

The layer structure of the organic compound layer is not particularly limited, and may be suitably selected in accordance with the usage of the organic electroluminescence element or the target thereof. Preferably, the organic compound layer is formed on the transparent electrode or on the back plate. In this case, the organic compound layer is formed on the front surface or the rear surface of the transparent electrode or the back plate.

The shape, the size, the thickness and other factors of the organic compound layer are not particularly limited, and can be suitably selected in accordance with the target.

Specific examples of the layer structure include the following. In the invention, however, the layer structure is not limited to these structures.
1. Anode/hole transporting layer/light emitting layer/electron transporting layer/cathode
2. Anode/hole transporting layer/light emitting layer/blocking layer/electron transporting layer/cathode
3. Anode/hole transporting layer/light emitting layer/blocking layer/electron transporting layer/electron injecting layer/cathode
4. Anode/hole injecting layer/hole transporting layer/light emitting layer/blocking layer/electron transporting layer/cathode
5. Anode/hole injecting layer/hole transporting layer/light emitting layer/blocking layer/electron transporting layer/electron injecting layer/cathode

Each of the layers will be described in detail hereinafter.

2) Hole Transporting Layer

The hole transporting layer used in the invention comprises a hole transporting material. As the hole transporting material, a material having any one of a function of transporting holes and a function of blocking electrons injected from the cathode can be used without any special limitation. The hole transporting material used in the invention may be any one of a low molecular weight hole transporting material and a high molecular weight hole transporting material.

Specific examples of the hole transporting material used in the invention include the following:

A carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stylbene derivative, a silazane derivative, an aromatic tertiary amine compound, a styrylamine compound, an aromatic dimethylidene compound, a porphyrin compound, a polysilane compound, a poly(N-vinylcarbazole) derivative, electro conductive polymers or oligomers such as an aniline copolymer, a thiophene oligomer and polythiophene, a polythiophene derivative, a polyphenylene derivative, a polyphenylenevinylene derivative, a polyfluorene derivative, and other polymer compounds.

These may be used alone or in combination of two or more kinds thereof.

The thickness of the hole transporting layer is preferably 10 to 200 nm, more preferably 20 to 80 nm. If the thickness is more than 200 nm, the driving voltage may rise. If the thickness is less than 10 nm, the electroluminescence element may unfavorably short-circuit.

3) Hole Injecting Layer

In the invention, a hole injecting layer may be formed between the hole transporting layer and the anode.

The hole injecting layer is a layer which makes it easy to inject holes from the anode to the hole transporting layer. Specifically, a material having a small ionization potential among the above-mentioned various hole transporting materials is preferably used. Examples of the material include a phthalocyanine compound, a porphyrin compound, and a star-burst triarylamine compound. These can be preferably used.

The film thickness of the hole injecting layer is preferably 1 to 30 nm.

4) Light-emitting Layer

The light-emitting layer used in the invention comprises at least one light-emitting material, and may comprise a hole transporting material, an electron transporting material, and a host material if necessary.

The light-emitting material used in the invention is not particularly limited, and may be any one of a fluorescent light-emitting material and a phosphorescent light-emitting material. The phosphorescent light-emitting material is preferable from the viewpoint of light-emitting efficiency.

Examples of the fluorescent light-emitting material include a benzooxazole derivative, a benzoimidazole derivative, a benzothiazole derivative, a styrylbenzene derivative, a polyphenyl derivative, a diphenylbutadiene derivative, a tetraphenylbutadiene derivative, a naphthalimide derivative, a coumalin derivative, a perylene derivative, a perynone derivative, an oxadiazole derivative, an aldazine derivative, a pyralizine derivative, a cyclopentadiene derivative, a bisstyrylanthracene derivative, a quinacridone derivative, pyrrolopyridine derivative, a thiadiazolopyridine derivative, a styrylamine derivative, an aromatic dimethylidene compound, various metal complexes, typical example of which include a metal complex of an 8-quinolinol derivative or a rare earth complex, and polymeric compounds such as a polythiophene derivative, a polyphenylene derivative, a polyphenylenevinylene derivative, and a polyfluorene derivative. These may be used alone or in combination of two or more kinds thereof.

The phosphorescent light-emitting material is not particularly limited, and is preferably an orthometal metal complex or a porphyrin complex.

The above-mentioned orthometal metal complex is the generic name for the compound group mentioned in “Organic metal chemistry—basic and application—“written by Akio Yamamoto, p. 150, p. 232, Shokabo Publishing Co., Ltd., (published in 1982), “Photochemistry and photophysics of coordination compounds” written by H. Yersin, p. 71 to 77, p. 135 to 146, Springer-Verlag (published in 1987) and the like. It is advantageous to use the orthometal metal complex in the luminescent layer as the light-emitting material in terms of obtaining a high luminosity and an excellent light-emitting efficiency.

Various kinds of ligands can be used for forming the above-mentioned orthometal metal complex, and examples thereof are described in the above-mentioned articles. Among them, preferable examples of the ligands include a 2-phenyl pyridine derivative, a 7,8-benzoquinoline derivative, a 2-(2-thienyl) pyridine derivative, a 2-(1-naphtyl) pyridine derivative, a 2-phenyl quinoline derivative and the like. These derivatives may have a substituent in accordance with necessity. Moreover, the above-mentioned orthometal metal complex may have another ligand in addition to the above-mentioned ligand.

The orthometal metal complex used in the present invention can be synthesized by various known methods such as those mentioned in: Inorg Chem., vol. 30, p. 1685 (1991); Inorg Chem., vol. 27, p. 3464 (1988); Inorg Chem., vol. 33, p. 545(1994); Inorg. Chim. Acta, vol. 181, p. 245 (1991); J. Organomet. Chem., vol. 335, p. 293 (1987); J. Am. Chem. Soc. vol. 107, p. 1431 (1985); or the like.

Among the above-mentioned orthometal complexes, a compound which provide light emission by a triplet exciton can be preferably used in the present invention in terms of improvement of the light-emitting efficiency.

Moreover, among the porphyrin complexes, a porphyrin platinum complex is preferable. The phosphorescent light-emitting materials may be used alone or in combination of two or more kinds thereof. One or more kinds of the fluorescent light-emitting materials and one or more kinds of the phosphorescent light-emitting materials may be used together.

The host material is a material which has a function of moving energy from an excited state thereof to a fluorescent light-emitting material or a phosphorescent light-emitting material, so as to cause the fluorescent or phosphorescent light-emitting material to emit light.

The host material is not particularly limited if the material is a compound capable of moving the energy of its excitons to the light-emitting material, and can be suitably selected in accordance with the purpose of the electroluminescence element. Specific examples thereof include a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydorazone derivative, a stylbene derivative, a silazane derivative, an aromatic tertiary amine compound, a styrylamine compound, an aromatic dimethylidene compound, a porphyrin compound, an anthraquinodimethane derivative, an anthrone derivative, a diphenylquinone derivative, a thiopyrandioxide derivative, a carbodiimide derivative, a fluorenylidenemethane derivative, a distyrylpyrazine derivative, heterocyclic tetracarboxylic acid anhydrides such as naphthaleneperylene, various metal complexes, typical examples of which include metal complexes of a phthalocyanine derivative or 8-quinolinol derivative, metal phthalocyanine, and metal complexes each having, as a ligand thereof, benzooxazole or benzothiazole, electroconductive polymers/oligomers such as a polysilane compound, a poly(N-vinylcarbazole) derivative, an aniline copolymer, a thiophene oligomer and polythiophene, and polymeric compounds such as a polythiophene derivative, a polyphenylene derivative, a polyphenylenevinylene derivative and a polyfluorene derivative. These may be used alone or in combination of two or more kinds thereof.

The content by percentage of the host material in the light-emitting layer is preferably 0 to 99.9% by mass, more preferably 0 to 99.0% by mass.

5) Blocking Layer

A blocking layer may be formed between the light-emitting layer and the electron transporting layer in the invention. The blocking layer is a layer for restraining the diffusion of excitons generated in the light-emitting layer, or restraining holes from penetrating toward the cathode.

The material used in the blocking layer is not particularly limited if the material is a material capable of receiving electrons from the electron transporting layer and delivering the electrons to the light-emitting layer. The material may be an ordinary electron transporting material. Examples thereof include the following: a triazole derivative, an oxazole derivative, an oxadiazole derivative, a fluorenone derivative, an anthraquinodimethane derivative, an anthrone derivative, a diphenylquinone derivative, a thiopyrandioxide derivative, a carbodiimide derivative, a fluorenylidenemethane derivative, a distyrylpyrazine derivative, heterocyclic tetracarboxylic acid anhydrides such as naphthaleneperylene, various metal complexes, typical examples of which include metal complexes of a phthalocyanine derivative or 8-quinolinol derivative, metal phthalocyanine, and metal complexes each having, as a ligand thereof, benzooxazole or benzothiazole, electroconductive polymers/oligomers such as an aniline copolymer, a thiophene oligomer and polythiophene, and polymeric compounds such as a polythiophene derivative, a polyphenylene derivative, a polyphenylenevinylene derivative and a polyfluorene derivative. These may be used alone or in combination of two or more kinds thereof.

6) Electron Transporting Layer

An electron transporting layer comprising an electron transporting material can be deposited in the invention.

The electron transporting material is not limited if the material is a material having any one of a function of transporting electrons and a function of blocking holes injected from the anode. Examples of the electron transporting material given in the description of the blocking layer can be preferably used.

The thickness of the electron transporting layer is preferably 10 to 200 nm, more preferably 20 to 80 nm.

If the thickness is more than 200 nm, the driving voltage may unfavorably rise. If the thickness is less than 10 nm, the light-emitting element may unfavorably short-circuit.

7) Electron Injecting Layer

An electron injecting layer may be formed between the electron transporting layer and the cathode in the invention.

The electron injecting layer is a layer which makes it easy to inject electrons from the cathode to the electron transporting layer. Preferable examples of the material used in this layer include alkali metal salts such as lithium fluoride, lithium chloride, lithium bromide, other lithium salts, sodium fluoride, sodium chloride and cesium fluoride, and insulating metal oxides such as lithium oxide, aluminum oxide, indium oxide and magnesium oxide.

The film thickness of the electron injecting layer is preferably 0.1 to 5 nm.

8) Method for Forming the Organic Compound Layer

The organic compound layer can be suitably formed by any method selected from dry film-forming methods such as vapor deposition and sputtering, and wet film-forming methods such as dipping, spin coating, dip coating, casting, die coating, roll coating, bar coating, and gravure coating. The dry methods are in particular preferable from the viewpoint of the light-emitting efficiency and durability of the film.

The following will describe the substrate and the electrodes used in the organic electroluminescence element of the invention.

9) Substrate

The material of the substrate used in the invention is preferably a material through which water content cannot permeate, or a material having a very low water content permeability. Also, the material is preferably a material which does not cause scattering or attenuation of light emitted from the organic compound layer. Specific examples thereof include inorganic materials such as YSZ (zirconia-stabilized yttrium) and glass, and organic materials such as polyethylene terephthalate, polybutylene terephthalate, polyethylene naphthalate, other polyesters, polystyrene, polycarbonate, polyethersulfone, polyarylate, allyl diglycol carbonate, polyimide, polycycloolefin, norbornene resin, poly(chlorotrifluoroethylene) and other synthetic resins. In the case of the organic materials, it is preferred that the organic materials are organic materials excellent in heat resistance, dimensional stability, solvent resistance, electric non-conductance, workability, low gas permeability and low hygroscopicity. In the case that the above-mentioned material of the transparent electrode is indium tin oxide (ITO), which is preferably used as the material of this transparent electron, preferable is a material having a lattice constant small in difference from that of ITO among these compounds. The above-mentioned materials may be used alone or in combination of two or more kinds thereof.

The shape, structure and size of the substrate and other factors thereof are not particularly limited, and can be suitably selected in accordance with the usage and purpose of the electroluminescence element. In general, the shape is a shape of a plate. The structure may be a mono-layered structure or a laminated structure. The substrate may be made of a single member, or two or more members.

The substrate may be transparent and colorless, or transparent and colored. The substrate is preferably transparent and colorless since the substrate does not cause scattering or attenuation of light emitted from the light-emitting layer.

It is preferable to form a moisture permeation preventing layer (gas barrier layer) on the front surface or the rear surface (on the side of the transparent electrode) of the substrate. The material of this layer is preferably an inorganic material such as silicon nitride or silicon oxide. This layer can be formed by, for example, high-frequency sputtering.

If necessary, a hard coat layer, an undercoat layer, or some other layer may be formed on the substrate.

10) Anode

It is usually sufficient that the anode used in the invention has a function of supplying holes to the organic compound layer. The shape, structure and size thereof, and other factors thereof are not particularly limited, and can be suitably selected from known anodes in accordance with the usage and the purpose of the electroluminescence element.

Preferable examples of the material of the anode include metals, alloys, metal oxides, organic electroconductive compounds, and mixtures thereof. The material is preferably a material having a work function of 4.0 eV or more. Specific examples thereof include semiconductive metal oxides such as a tin oxide doped with antimony or fluorine (ATO, or FTO), tin oxide, zinc oxide, indium oxide, indium tin oxide (ITO) and indium zinc oxide (IZO), metals such as gold, silver, chromium and nickel, mixtures or laminates each made of one or more of these metals and an electroconductive metal oxide, inorganic electroconductive materials such as copper iodide and copper sulfide, organic electroconductive materials such as polyaniline, polythiophene and polypyrrole, and laminates each composed of one or more of these compounds and ITO.

The anode can be formed on the substrate in accordance with a method selected suitably, under consideration of suitability for the anode material, from wet methods such as printing and coating, physical methods such as vacuum vapor deposition, sputtering and ion plating, chemical methods such as CVD and plasma CVD, and other methods. In the case of selecting, for example, ITO as the anode material, the anode can be formed by direct current or high-frequency sputtering, vacuum vapor deposition, ion plating or the like. In the case of selecting an organic electroconductive compound as the anode material, the anode can be formed by any wet film-forming method.

The position where the anode is formed in the electroluminescence element is not particularly limited, and can be suitably selected in accordance with the usage and the purpose of this element. The anode is preferably formed on the substrate. In this case, the anode may be formed on the whole of a surface of the substrate or on a part of the surface.

The anode may be patterned by a chemical etching such as photolithography or a physical etching such as laser etching. The patterning may be attained by vacuum vapor deposition or sputtering in a state that a mask is overlapped with the anode which has not yet been patterned, or may be attained by a lift-off method or a printing method.

The thickness of the anode can be suitably selected in accordance with the anode material. The thickness, which cannot be specified without reservation, is usually from 10 nm to 50 μm, preferably 50 nm to 20 μm.

The resistance value of the anode is preferably 10³ Ω/□ or less, more preferably 10² Ω/□ or less.

The anode may be transparent and colorless, or transparent and colored. In order to take out light emitted from the side of the anode, the transmittance thereof is preferably 60% or more, more preferably 70% or more. This transmittance can be measured in a known method using a spectrophotometer.

Details of anodes are described in “New Development of Transparent Electrode Films”, supervised by Yutaka Sawada and published by CMC (1999). These can be applied to the invention. The anode in the case of using a plastic substrate with low heat resistance is preferably an anode obtained by making ITO or IZO into a film at a low temperature of 150° C. or lower.

11) Cathode

It is usually sufficient that the cathode, which can be used in the invention, has a function of injecting electrons into the organic compound layer. The shape, structure and size thereof, and other factors thereof are not particularly limited, and can be suitably selected from known cathodes in accordance with the usage and the purpose of the electroluminescence element.

Examples of the material of the cathode include metals, alloys, metal oxides, organic electroconductive compounds, and mixtures thereof. The material is preferably a material having a work function of 4.5 eV or less. Specific examples thereof include alkali metals (such as Li, Na, K and Cs), alkaline earth metals (such as Mg, and Ca), gold, silver, lead, aluminum, sodium-potassium alloy, lithium-aluminum alloy, magnesium-silver alloy, indium, and rare earth metals such as ytterbium. These may be used alone. However, in order to make the stability and electron-injecting property of the cathode compatible with each other, it is preferable to use two or more kinds thereof together.

Among them, alkali metals or alkaline earth metals are preferable from the viewpoint of electron injecting property. A material made mainly of aluminum is preferable since the material is excellent in storage stability. The material made mainly of aluminum means aluminum alone, or any alloy or mixture made of aluminum and 0.01 to 10% by mass of an alkali metal or alkaline earth metal (for example, lithium-aluminum alloy, or magnesium-aluminum alloy).

Materials of the cathode are described in detail in Japanese Patent Application Laid-Open (JP-A) Nos. 2-15595 and 5-121172. These can be applied to the invention.

The method for forming the cathode is not particularly limited, and may be a known method. For example, the cathode can be formed on the substrate in accordance with a method selected suitably, under consideration of suitability for the cathode material, from wet methods such as printing and coating, physical methods such as vacuum vapor deposition, sputtering and ion plating, chemical methods such as CVD and plasma CVD, and other methods. In the case of selecting, for example, one or two or more kinds metals as the cathode material, the cathode can be formed thinly by sputtering the metal or by sputtering the metals simultaneously or successively.

The cathode may be patterned by a chemical etching such as photolithography or a physical etching such as laser etching. The patterning may be attained by vacuum vapor deposition or sputtering in a state that a mask is overlapped with the cathode which has not yet been patterned, or may be attained by a lift-off method or a printing method.

The position where the cathode is formed in the organic electroluminescence element is not particularly limited, and can be suitably selected in accordance with the usage and the purpose of this element. The cathode is preferably formed on the organic compound layer. In this case, the cathode may be formed on the whole of the organic compound layer or on a part of the layer.

A dielectric layer made of an alkali metal fluoride, an alkaline earth metal fluoride or the like may be inserted between the cathode and the organic compound layer so as to have a thickness of 0.1 to 5 nm.

The dielectric layer may be formed by, for example, vacuum vapor deposition, sputtering or ion plating.

The thickness of the cathode can be suitably selected in accordance with the cathode material. The thickness, which cannot be specified without reservation, is usually from 10 nm to 5 82 m, preferably 50 nm to 1 μm.

The cathode may be transparent or opaque. The transparent electrode can be formed by making the cathode material into a film having a small thickness of 1 to 10 nm and then laminating a transparent electroconductive material such as ITO or IZO onto the film.

12) Other Layers

Other layers can be suitably selected in accordance with the purpose without any limitation. For example, a protective layer or a sealing layer can be used.

<Protective Layer>

Preferable examples of the protective layer include protective layers described in JP-A Nos. 7-85974, 7-192866, 8-22891, 10-275682 and 10-106746.

The protective layer is formed on one of the outermost surfaces of the organic electroluminescence element. For example, in the case of laminating, onto the substrate, the anode, the organic compound layer and the cathode in this order, the protective layer is formed on the cathode. In the case of laminating, onto the substrate, the cathode, the organic compound layer and the anode in this order, the protective layer is formed on the anode.

The shape, size and thickness of the protective layer and other factors thereof can be suitably selected. The material thereof is not particularly limited if the material has a function of restraining substances causing a deterioration in the electroluminescence element, such as water content and oxygen, from penetrating or permeating into this element. Examples of the material include silicon oxide, silicon dioxide, germanium oxide, and germanium dioxide.

The method for forming the protective layer is not particularly limited, and examples thereof include vacuum vapor deposition, sputtering, reactive sputtering, molecular beam epitaxy, cluster ion beam technique, ion plating, plasma polymerization, plasma CVD, laser CVD, thermal CVD, and coating.

<Sealing Layer>

In the invention, it is also preferable to form a sealing layer in order to prevent the invasion of water content or oxygen into each of the layers in the organic electroluminescence element.

Examples of the material of the sealing material include a copolymer made from tetrafluoroethylene and at least one comonomer, a fluorine-containing copolymer having, in its main chain, a cyclic structure, two or more copolymers selected from polyethylene, polypropylene, polymethyl methacrylate, polyimide, polyurea, polytetrafluoroethylene, polychlorotrifluoroethylene, polydichlorodifluoroethylene, chlorotrifluoroethylene and dichlorodifluoroethylene, a water-absorbable material having a water absorption of 1% or more, a moisture-proof material having a water absorption of 0.1% or less, metals such as In, Sn, Pb, Au, Cu, Ag, Al, Ti and Ni, metal oxides such as MgO, SiO, SiO₂, Al₂O₃, GeO, NiO, CaO, BaO, Fe₂O₃, Y₂O₃ and TiO₂, metal fluorides such as MgF₂, LiF, AlF₃ and CaF₂, liquid carbon fluorides such as perfluoroalkane, perfluoroamine and perfluoroether, and a material wherein an absorbent for absorbing water content and oxygen is dispersed in a liquid carbon fluoride.

13) Means for Controlling the Localized Level

In the organic electroluminescence element of the invention, at least one organic compound layer does not substantially have any localized level between the highest occupied molecular orbit (HOMO) and the lowest unoccupied molecular orbit (LUMO) of the material which constitutes the organic compound layer. This organic compound layer may be any one of the above-mentioned hole transporting layer, hole injecting layer, light-emitting layer, blocking layer, electron transporting layer and electron injecting layer. It is preferable that each of plural organic compound layers does not substantially have any localized level between the highest occupied molecular orbit (HOMO) and the lowest unoccupied molecular orbit (LUMO) of the material which constitutes the organic compound layer. It is more preferable that each of all organic compound layers in this element does not substantially have any localized level between the highest occupied molecular orbit (HOMO) and the lowest unoccupied molecular orbit (LUMO) of the material which constitutes the organic compound layer.

The organic electroluminescence element of the invention is an organic semiconductor element wherein at least one organic semiconductor thin film does not have any current peak observed substantially in a temperature range of measurement temperatures of 100 to 200 K in measurement based on a thermally stimulated current measuring method (TSC method). This organic compound layer may be any one of the above-mentioned hole transporting layer, hole injecting layer, light-emitting layer, blocking layer, electron transporting layer and electron injecting layer. It is preferable that each of plural organic compound layers does not substantially have any current peak observed in a temperature range of measurement temperatures of 100 to 200 K in measurement based on a thermally stimulated current measuring method (TSC method). It is more preferable that each of all organic compound layers in this element does not substantially have any current peak observed in a temperature range of measurement temperatures of 100 to 200 K in measurement based on a thermally stimulated current measuring method (TSC method).

It is preferable that in the organic electroluminescence element of the invention, at least one organic compound layer comprises at least one of a hole transporting material and an electron transporting material, and an electrically inactive organic compound having an energy difference (Eg) between the HOMO and the LUMO of 4.0 eV or more. In the invention, the organic compound is preferably an aromatic hydrocarbon compound. Furthermore, in the organic electroluminescence element of the invention, at least one organic compound layer preferably comprises an aromatic hydrocarbon compound represented by the following Formula (1) or (3).
L-(Ar)ₘ Formula (1)

In Formula (1), Ar is a group represented by the following Formula (2), L is a phenyl group having a valence of 3 or more, and m is an integer of 3 or more.

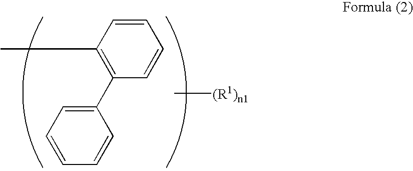

wherein R¹ is a substituent; in the case where R¹ is present in a plurality, they may either be the same or different from each other; and n1 is an integer from 0 to 9.

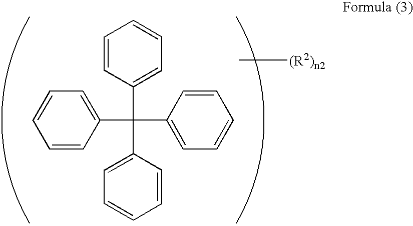

About Formulae (1), (2) and (3), details and specific examples thereof are the same as described above.

The aromatic hydrocarbon compound represented by Formula (1) or (3) may be contained in any one of the above-mentioned hole transporting layer, hole injecting layer, light-emitting layer, blocking layer, electron transporting layer and electron injecting layer, or may contained in plural ones of these layers or in all of the layers. When the aromatic hydrocarbon compound represented by Formula (1) or (3) is incorporated into at least one of the organic compound layers, the organic compound layer can be rendered an organic compound layer which does not substantially have any current peak observed in a temperature range of measurement temperatures of 100 to 200 K in measurement based on a thermally stimulated current measuring method (TSC method), that is, an organic compound layer having no localized level.

When the aromatic hydrocarbon compound represented by Formula (1) or (3) is incorporated into the hole transporting layer, the hole injecting layer, the light-emitting layer, or any other layer having hole transportability, the electron affinity of the aromatic hydrocarbon compound represented by Formula (1) or (3) is preferably less than 2.3 eV. When the affinity is less than 2.3 eV, electrons can be restrained from being injected into the above-mentioned layer having hole transportability.

When the aromatic hydrocarbon compound represented by Formula (1) or (3) is incorporated into the electron transporting layer, the electron injecting layer, the blocking layer, the light-emitting layer, or any other layer having electron transportability, the ionization potential of the aromatic hydrocarbon compound represented by Formula (1) or (3) is preferably more than 6.1 eV. When the ionization potential is more than 6.1 eV, holes can be restrained from being injected into the above-mentioned layer having electron transportability.

In the case that a phosphorescent light-emitting material is used in the light-emitting layer of the electroluminescence element of the invention, the aromatic hydrocarbon compound represented by Formula (1) or (3) may be used in the light-emitting layer or a layer adjacent to the light-emitting layer. In this case, the lowest triplet excitation level T1 of the aromatic hydrocarbon compound represented by Formula (1) or (3) is preferably 2.7 eV or more. This causes energy of excitons not to be trapped by the aromatic hydrocarbon compound represented by Formula (1) or (3) so as to make the efficiency of the organic electroluminescence element higher.

The organic electroluminescence element of the invention preferably comprises the hole transporting material and/or the electron transporting material, and an electrically inactive compound having an energy difference (Eg) between the HOMO and the LUMO of 4.0 eV or more, and the blend ratio is preferably 95/5 to 30/70% by mass, more preferably 95/5 to 40/60% by mass. If the ratio of the electrically inactive compound is smaller than this lower limit, the effect of removing any localized level becomes small. If this ratio is larger than the upper limit, the semiconductor characteristics of the hole transporting material and/or the electron transporting material, such as the charge mobility, are damaged.

In the organic electroluminescence element of the invention, at least one organic compound layer is caused not to have any localized level between the highest occupied molecular orbit (HOMO) and the lowest unoccupied molecular orbit (LUMO) of the material which constitutes the organic compound layer, whereby the light-emitting efficiency of this organic electroluminescence element can be improved and the durability thereof can be made high.

The electroluminescence element of the invention can emit light by applying a direct current (which may contain an alternating current component if necessary) voltage (usually, 2 to 40 volts) or a direct current to the anode and the cathode across these electrodes.

The electroluminescence element of the invention can be driven by a method described in JP-A Nos. 2-148687, 6-301355, 5-29080, 7-134558, 8-234685 or 241047, USP Nos. 5828429 or 6023308, Japanese Patent No. 2784615, or the like.

Exemplary aspects of the invention are listed below.
<1>An organic semiconductor thin film comprising at least one organic compound of a hole transporting material and/or an electron transporting material, wherein a localized level is not substantially present between a highest occupied molecular orbit (HOMO) and a lowest unoccupied molecular orbit (LUMO) of the film.
<2>An organic semiconductor thin film comprising at least one organic compound of a hole transporting material and/or an electron transporting material, the film substantially not having any current peak observed in a temperature range of measurement temperatures of 100 to 200 K in a measurement based on a thermally stimulated current measuring method.
<3>The organic semiconductor thin film of <1>or <2>, which comprises an organic compound having an energy difference (Eg) between the HOMO and the LUMO of 4.0 eV or more.
<4>The organic semiconductor thin film of <3>, wherein the organic compound is an aromatic hydrocarbon compound.
<5>The organic semiconductor thin film of <4>, wherein the aromatic hydrocarbon compound is a compound represented by the following Formula (1):
   L-(Ar)ₘ Formula (1)

wherein, in the Formula (1), Ar is a group represented by the following Formula (2), L is a phenyl group having a valence of 3 or more, and m is an integer of 3 or more.

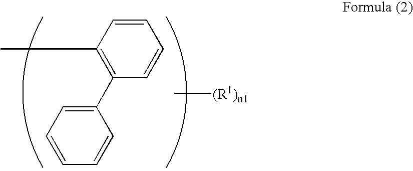

wherein R¹ is a substituent which can be substituted with benzene ring ; when R¹ is present in plurality, each R¹ may be the same as or different from another R¹; and n1 is an integer from 0 to 9.
<6>The organic semiconductor thin film of <5>, wherein R¹ in Formula (2) comprises a substituent selected from alkyl, aryl and heteroaryl groups.
<7>The organic semiconductor thin film of <5>, wherein n1 in Formula (2) is an integer of from 0 to 6.
<8>The organic semiconductor film of <4>, wherein the aromatic hydrocarbon compound is represented by the following Formula (3):

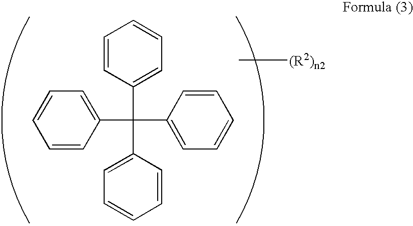

wherein R² is a substituent which can be substituted with benzene ring ; when R² is present in plurality, each R² may be the same as or different from another R²; and n2 is an integer from 0 to 20.
<9>The organic semiconductor thin film of any one of <4>to <8>, which comprises at least one organic compound of the hole transporting material and/or the electron transporting material, and an organic compound which has an energy difference (Eg) between the HOMO and the LUMO of 4.0 eV or more, wherein the blend ratio by mass is in the range of from 95/5 to 30/70.
<10>An organic semiconductor element, comprising one or more organic semiconductor thin films between a pair of electrodes, wherein at least one of the organic semiconductor thin films is the organic semiconductor thin film of any one of <1>to <9>.
<11>An organic electroluminescence element, comprising one or more organic compound layers between a pair of electrodes, wherein at least one of the organic compound layers is the organic semiconductor thin film of any one of <1>to <9>.

### EXAMPLES

The organic semiconductor thin film and the organic electroluminescence element of the invention will be specifically described by way of the following examples. However, the invention is not limited to these examples.

### Example 1

1. Production of an Organic Semiconductor Thin Film

A glass plate 2.5 cm square and 0.7 mm in thickness, was used as a substrate, and this substrate was introduced into a vacuum chamber. An ITO target containing 10% by mass of SnO₂ (molar ratio of indium to tin=95/5) was used to form an ITO thin film (thickness: 0.2 μm) as a transparent electrode on the substrate by DC magnetron sputtering (conditions: substrate temperature of 250° C. and oxygen pressure of 1×10⁻³ Pa). The surface resistance of the ITO thin film was 10Ω/□.

Next, the substrate on which the transparent electrode was formed was put into a washing container, washed with IPA, and subjected to UV-ozone treatment for 30 minutes.

N,N′-dinaphthyl-N,N′-diphenylbenzidine (NPD) and organic compound (1) of the present invention represented by Formula (1) were co-deposited at a ratio of 75/25 onto the transparent electrode by vacuum vapor deposition to a thickness of 0.1 μm.

Furthermore, a patterned mask (giving a light emission area of 2 mm×2 mm) was set onto this electron injecting layer, and then aluminum was vapor-deposited inside a vapor deposition machine to a thickness of 0.25 μm. In this way, a back plate electrode was formed.

Lead wires made of aluminum were connected to the transparent electrode (functioning as an anode) and the back plate electrode, so as to form an organic semiconductor thin film of the invention.

The thus-obtained organic semiconductor thin film was put into a glove box purged with nitrogen gas. 10 mg of calcium oxide powder as a water absorbent was put into the glove box and a stainless steel sealing cover provided with a concave portion at an inner side thereof was affixed with an adhesive tape. This sealing cover and an ultraviolet curable adhesive (XNR5516HV, manufactured by Nagase Ciba) as an adhesive were used to seal the film. In this way, an organic semiconductor thin film of Example 1 was produced.

2. Performance Evaluation

The organic semiconductor thin film produced as described above was evaluated by the following method.

A thermal stimulus current measurement (TSC) of the film was made using a thermal stimulus current meter TS-FETT manufactured by Rigaku Corp. The organic semiconductor thin film sample was cooled to 93 K (−180° C.) at a rate of −5 K/min. The sample was allowed to stand at this temperature for 20 minutes, and then irradiated with light having a wavelength of 330 nm for 5 minutes to generate a photocurrent, thereby causing electric charges to be trapped at a localized level of the sample. Thereafter, the sample was heated to 273 K (0° C.) at a rate of 10 K/min. The current that flowed at this time was measured.

The measurement results are shown in Table 4. It can be understood from the results that there was not any substantial peak in a temperature range of 100 to 200 K, and thus no localized level was present.

A sample for charge mobility measurement was produced in exactly the same manner as described above except that the thickness of the organic layer was changed from 0.1 to 1.0 μm. The charge mobility was measured by a time-of-flight method using a time-of-flight meter manufactured by Kabushiki Kaisha Optel [transliteration]. As a result, the hole mobility was a very large value of 2×10⁻² cm² /V.second at an electric field of 1.0×10⁶ V/cm.

### Comparative Example 1

1. Production of a Sample

An organic layer 0.1 μm in thickness was formed from N,N′-dinaphthyl-N,N′-diphenylbenzidine (NPD) alone, instead of depositing NPD and organic compound (1) represented by Formula (1) at the ratio of 75/25 into the film 0.1 μm in thickness as in Example 1. Otherwise in the same manner as in Example 1, electrodes were formed and sealing was performed to produce an organic semiconductor thin film of Comparative Example 1.

2. Performance Evaluation

A TSC measurement of the resultant organic semiconductor thin film was made in the same manner as in Example 1. The results are shown in FIG. 3. It is understood therefrom that in Comparative Example 1 a peak was observed in a temperature range of 100 to 200 K and thus a localized level was present.

A sample for charge mobility measurement was produced in the same manner as in Example 1, and the charge mobility was measured in the same manner as in Example 1. As a result, the hole mobility was 2.65×10⁻³ cm²/V.second at an electric field of 1.0×10⁶ V/cm, and was smaller as compared with the organic semiconductor thin film of Example 1.

### Example 2

An organic semiconductor thin film of Example 2 was produced in the same manner as in Example 1 except that 4,4′-N,N′-dicarbazolebiphenyl (CBP) and organic compound (1) represented by Formula (1) were co-deposited, at a ratio of 50/50, into a film 0.1 μm in thickness by vacuum vapor deposition instead of co-depositing N,N′-dinaphthyl-N,N′-diphenylbenzidine (NPD) and organic compound (1) represented by Formula (1), at the ratio of 75/25, into the organic layer 0.1 μm in thickness by the vacuum vapor deposition in Example 1.

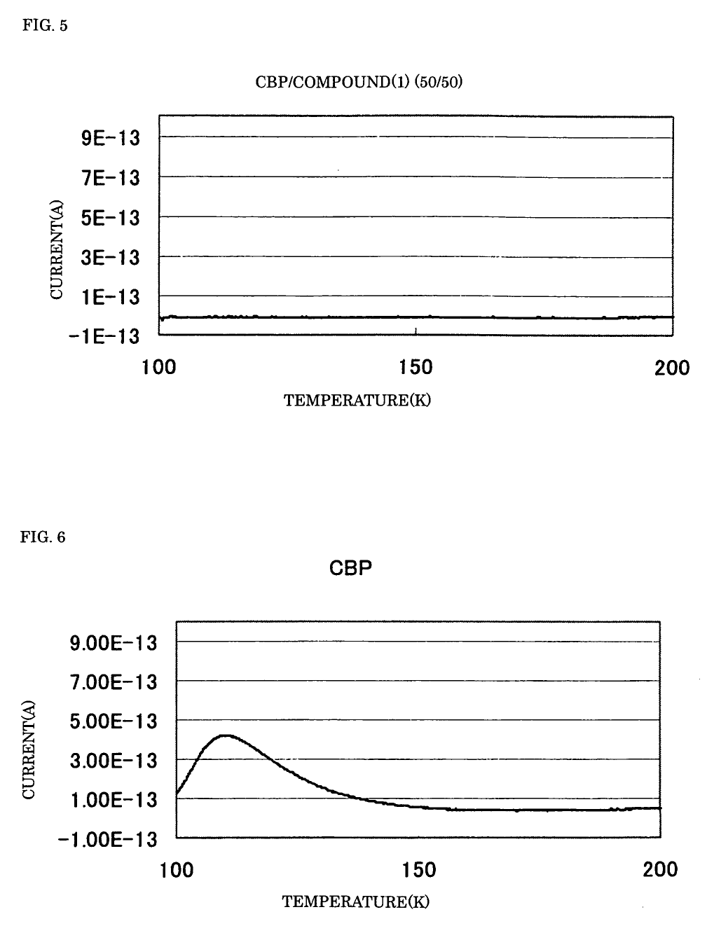

A TSC measurement of this organic semiconductor thin film sample was made in the same manner as in Example 1. The measurement results are shown in FIG. 5. It can be understood from the results that there was not any substantial peak in a temperature range of 100 to 200 K, and thus no localized level was present.

A sample for charge mobility measurement was produced in the same manner as in Example 1. The charge mobility was measured in the same manner as in Example 1. As a result, the hole mobility was a large value of 8.9×10⁻³ cm²/V.second at an electric field of 1.0×10⁶ V/cm.

### Comparative Example 2

An organic layer 0.1 μm in thickness was formed from 4,4′-N,N′-dicarbazolebiphenyl (CBP) alone instead of depositing CBP and organic compound (1) represented by Formula (1) at the ratio of 50/50 into the film 0.1 μm in thickness by the vacuum vapor deposition in Example 2. In the same manner as in Example 2 except this, electrodes were formed and sealing was performed to produce an organic semiconductor thin film of Comparative Example 2.

A TSC measurement of this organic semiconductor thin film was made in the same manner as in Example 2. The results are shown in FIG. 6. It is understood therefrom that in Comparative Example 2 a peak was observed in a temperature range of 100 to 200 K and thus a localized level was present.

A sample for charge mobility measurement was produced in the same manner as in Example 1, and the charge mobility was measured in the same manner as in Example 1. As a result, the hole mobility was 2.34×10⁻³ cm²/V.second at an electric field of 1.0×10⁶ V/cm, and was smaller as compared with the organic semiconductor thin film of Example 2.

### Example 3

An organic semiconductor thin film of Example 3 was produced in the same manner as in Example 1 except that the following electron transporting material (59) and organic compound (1) represented by Formula (1) were co-deposited, at a ratio of 40/60, into a film 0.1 μm in thickness by vacuum vapor deposition instead of co-depositing N,N′-dinaphthyl-N,N′-diphenylbenzidine (NPD) and organic compound (1) represented by Formula (1) at the ratio of 75/25 into the organic layer, 0.1 μm in thickness, by the vacuum vapor deposition in Example 1.

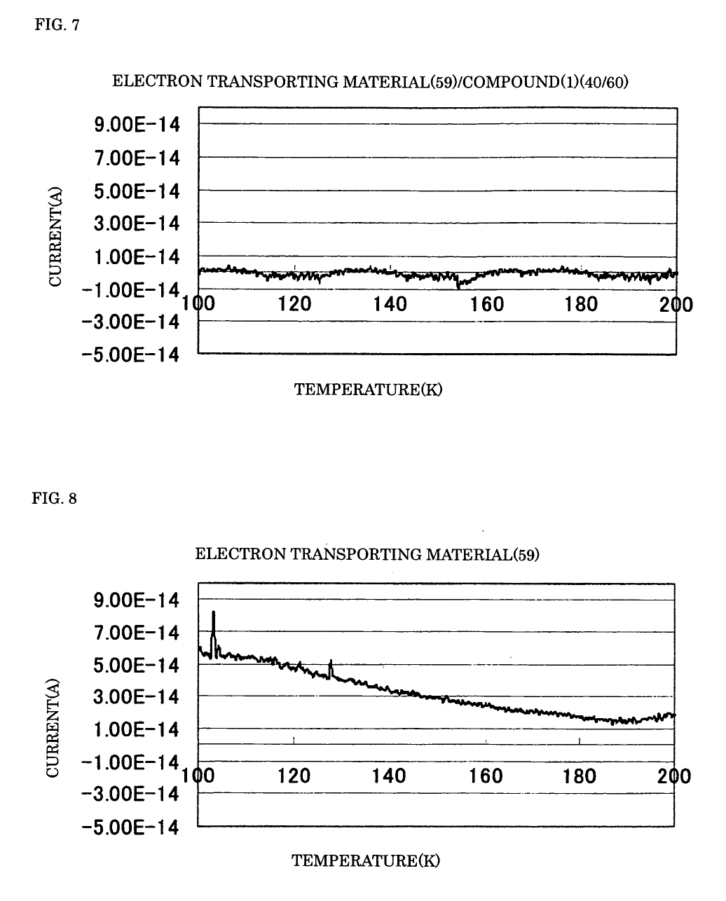

A TSC measurement of this organic semiconductor thin film sample was made in the same manner as in Example 1. The measurement results are shown in FIG. 7. It can be understood from the results that there was not any substantial peak in a temperature range of 100 to 200 K, and thus no localized level was present.

A sample for charge mobility measurement was produced in the same manner as in Example 1. The charge mobility was measured in the same manner as in Example 1. As a result, the electron mobility was a large value of 6.8×10⁻³ cm²/V.second at an electric field of 1.0×10⁶ V/cm.

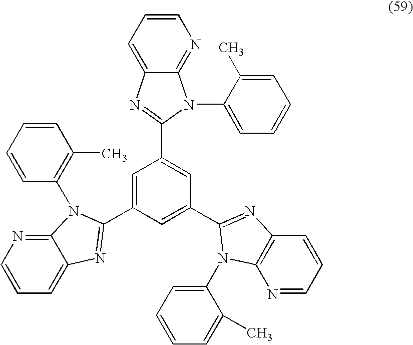

### Comparative Example 3

An organic layer 0.1 μm in thickness was formed from above-mentioned electron transporting material (59) alone instead of depositing electron transporting material (59) and organic compound (1) represented by Formula (1) at the ratio of 40/60 into the film 0.1 μm in thickness by the vacuum vapor deposition in Example 3. In the same manner as in Example 2 except this, electrodes were formed and sealing was performed to produce an organic semiconductor thin film of Comparative Example 3.

A TSC measurement of this organic semiconductor thin film was made in the same manner as in Example 1. The results are shown in FIG. 8. It is understood therefrom that in Comparative Example 3 a peak was observed in a temperature range of 100 to 200 K and thus a localized level was present.

A sample for charge mobility measurement was produced in the same manner as in Example 1, and the charge mobility was measured in the same manner as in Example 1. As a result, the electron mobility was 9.03×10⁻⁴ cm²/V.second at an electric field of 1.0×10⁶ V/cm, and was smaller as compared with the organic semiconductor thin film of Example 3.

### Example 4

An organic semiconductor thin film of Example 4 was produced in the same manner as in Example 1 except that N,N′-dinaphthyl-N,N′-diphenylbenzidine (NPD) and organic compound (19) represented by Formula (1) were co-deposited, at a ratio of 75/25, into a film 0.1 μm in thickness by vacuum vapor deposition instead of co-depositing NPD and organic compound (1) represented by Formula (1) at the ratio of 75/25 into the organic layer 0.1 μm in thickness by the vacuum vapor deposition in Example 1.

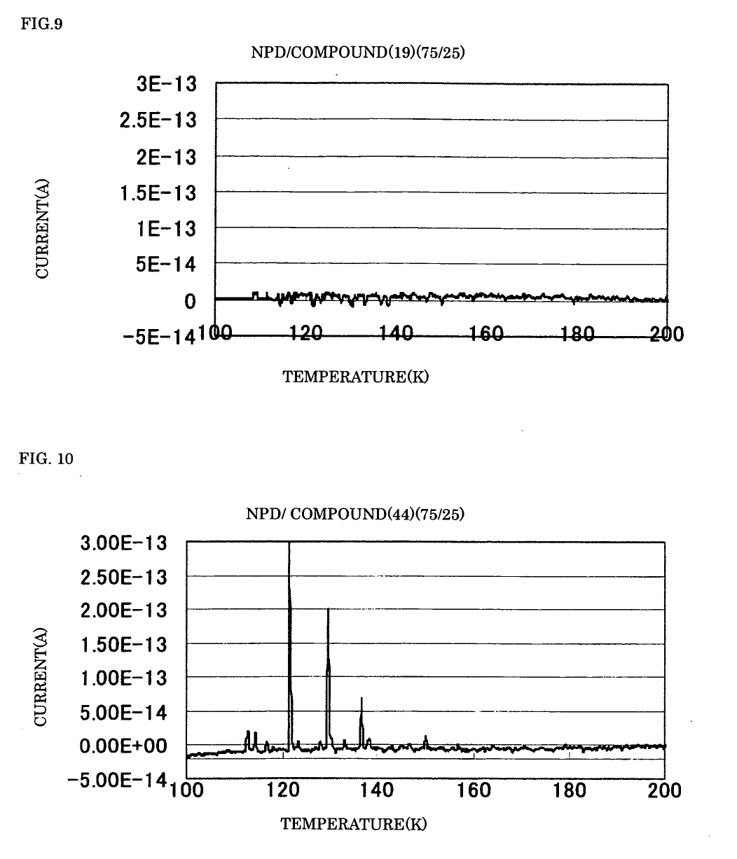

A TSC measurement of this organic semiconductor thin film sample was made in the same manner as in Example 1. The measurement results are shown in FIG. 9. It can be understood from the results that there was not any substantial peak in a temperature range of 100 to 200 K, and thus no localized level was present.

A sample for charge mobility measurement was produced in the same manner as in Example 1. The charge mobility was measured in the same manner as in Example 1. As a result, the hole mobility was a large value of 1.2×10⁻³ cm²/V.second at an electric field of 1.0×10⁶ V/cm.

### Example 5

An organic semiconductor thin film of Example 5 was produced in the same manner as in Example 1 except that N,N′-dinaphthyl-N,N′-diphenylbenzidine (NPD) and organic compound (44) represented by Formula (3) were co-deposited, at a ratio of 75/25, into a film 0.1 μm in thickness by vacuum vapor deposition instead of co-depositing NPD and organic compound (1) represented by Formula (1) at the ratio of 75/25 into the organic layer 0.1 μm in thickness by the vacuum vapor deposition in Example 1.

A TSC measurement of this organic semiconductor thin film sample was made in the same manner as in Example 1. The measurement results are shown in FIG. 10. It can be understood from the results that there was not any substantial peak in a temperature range of 100 to 200 K, and thus no localized level was present.

A sample for charge mobility measurement was produced in the same manner as in Example 1. The charge mobility was measured in the same manner as in Example 1. As a result, the hole mobility was a large value of 3.1×10⁻³ cm²/V.second at an electric field of 1.0×10⁶ V/cm.

### Example 6

### An Example of an Organic Electroluminescence Element

1. Production of a Sample

A glass plate 2.5 cm square, 0.5 mm in thickness, was used as a substrate, and this substrate was introduced into a vacuum chamber. An ITO target containing 10% by mass of SnO₂ (molar ratio of indium to tin=95/5) was used to form an ITO thin film (thickness: 0.2 μm) as a transparent electrode onto the substrate by DC magnetron sputtering (conditions: a substrate temperature of 250° C. and an oxygen pressure of 1×10⁻³ Pa). The surface resistance of the ITO thin film was 10Ω/□.

Next, the substrate on which the transparent electrode was formed was put into a washing container, washed with IPA, and subjected to UV-ozone treatment for 30 minutes.

Copper phthalocyanine was deposited into a hole injecting layer 0.01 μm in thickness on this transparent electrode at a rate of 1 nm/second by vacuum vapor deposition.

Next, a hole transporting layer was formed on this hole injecting layer as follows. N,N′-dinaphthyl-N,N′-diphenylbenzidine (NPD) as a hole transporting material and exemplified organic compound (1) as an organic compound represented by Formula (1) were co-deposited, at a vapor deposition ratio of 75/25 (the ratio=a molar ratio, this matter being applied in the same manner hereinafter), into the hole transporting layer 0.3 μm in thickness by vacuum vapor deposition.

A tris(2-phenylpyridyl)iridium complex (Ir(ppy)₃) as a phosphorescent light-emitting material and 4,4′-N,N′-dicarbazolebiphenyl (CBP) as a host compound were co-deposited, at a vapor deposition ratio of 5/100, into a light-emitting layer 0.03 μm in thickness onto the hole transporting layer by vacuum vapor deposition.

A blocking layer was formed on this light-emitting layer as follows. Aluminum (III) bis(2-methyl-8-quinolinato)4-phenylphenolate (Balq₂) was used as an electron transporting material for the blocking layer to be deposited into the blocking layer 0.01 μm in thickness at a rate of 1 nm/second by vacuum vapor deposition.

Furthermore, tris(8-hydroxyquinolinato)aluminum (Alq₃) was used as an electron transporting material to be deposited into an electron transporting layer 0.04 μm in thickness on the blocking layer by vacuum vapor deposition.

Furthermore, LiF as an electron injecting material was deposited into an electron injecting layer 0.002 μm in thickness on the electron transporting layer at a rate of 1 nm/second by vapor deposition.

Furthermore, a patterned mask (giving a light emission area of 2 mm×2 mm) was set onto this electron injecting layer, and then aluminum was vapor-deposited inside a vapor deposition machine to give a thickness of 0.25 μm. In this way, a back plate electrode was formed.

Lead wires made of aluminum were connected to the transparent electrode (functioning as an anode) and the back plate electrode, so as to form a luminescent laminate.

The thus-obtained luminescent laminate was put into a glove box purged with nitrogen gas. In the glove box, 10 mg of calcium oxide powder as a water absorbent was put into a stainless steel sealing cover given with a concave portion at an inner side thereof, and then the cover was affixed with an adhesive tape. This sealing cover and an ultraviolet curable type adhesive (XNR5516HV, manufactured by Nagase Ciba) as an adhesive were used to seal the film.

In this way, an organic electroluminescence element of Example 6 was produced.

2. Performance Evaluation

The produced organic electroluminescence element was evaluated by the following method.

A source measure unit, 2400 model, manufactured by Toyo Technica Inc. was used to apply a DC voltage to the organic electroluminescence element, thereby causing this element to emit light. The initial luminescent performance of the element was then measured. The maximum luminance at this time was defined as Lmax, and the voltage at which Lmax was obtained was defined as Vmax. The light-emitting efficiency when the luminance was 2000 Cd/m² was defined as external quantum efficiency (η₂₀₀₀). The obtained results are shown in Table 1.

In a driving durability test, the organic electroluminescence element was continuously driven from an initial luminance of 1000 Cd/m², and the period when the luminance was reduced by half was obtained as the half-value period (T_{1/2}). The results are shown in Table 1.

The Eg, the T1 and the electron affinity (Ea) of each of the organic compounds represented by Formula (1) or (3) were checked by the following method. Each of these values is shown in Table 2.

The Eg was obtained on the basis of an absorption end of the absorption spectrum of the vapor-deposited film made of compound (1) alone.

The T1 was obtained on the basis of a rise wavelength observed when the sample of compound (1) was cooled below the temperature of liquid nitrogen and phosphorescence therefrom was measured.

The electron affinity was obtained as follows: the sample of compound (1) was put into the atmosphere; the ionization potential (Ip) was measured by means of an ultraviolet photoelectron analyzer AC-1 (manufactured by Riken Keiki Co., Ltd.); and then the value of the Eg was subtracted from the measured ionization potential.

### Example 7

An organic electroluminescence element was produced and then evaluated in the same manner as in Example 6 except that exemplary compound (4) was used instead of exemplary compound (1) as the organic compound represented by Formula (1) and used for the hole transporting layer in Example 6. The results are shown in Tables 1 and 2.

### Example 8

An organic electroluminescence element was produced and then evaluated in the same manner as in Example 6 except that exemplary compound (7) was used instead of exemplary compound (1) as the organic compound represented by Formula (1) and used for the hole transporting layer in Example 6. The results are shown in Tables 1 and 2.

### Example 9

An organic electroluminescence element was produced and then evaluated in the same manner as in Example 6 except that exemplary compound (19) was used instead of exemplary compound (1) as the organic compound represented by Formula (1) and used for the hole transporting layer in Example 6. The results are shown in Tables 1 and 2.

### Example 10

An organic electroluminescence element was produced and then evaluated in the same manner as in Example 6 except that exemplary compound (34) represented by Formula (3) was used instead of exemplary compound (1) used for the hole transporting layer in Example 6. The results are shown in Tables 1 and 2.

### Example 11

An organic electroluminescence element was produced and then evaluated in the same manner as in Example 6 except that exemplary compound (44) represented by Formula (3) was used instead of exemplary compound (1) used for the hole transporting layer in Example 6. The results are shown in Tables 1 and 2.

### Comparative Example 4

An organic electroluminescence element was produced and then evaluated in the same manner as in Example 6 except that a hole transporting layer made of NPD alone was formed without using exemplary compound (1) used for the hole transporting layer in Example 6. The results are shown in Tables 1 and 2.

TABLE 1

| | Lmax (Cd/m2) | Vmax (V) | η max (%) | T½ (hours) |
|---|---|---|---|---|
| Example 6 | 78000 | 15 | 14.1 | 1600 |
| Example 7 | 75000 | 15 | 13.4 | 1600 |
| Example 8 | 72000 | 15 | 12.3 | 1300 |
| Example 9 | 78000 | 16 | 13.0 | 1500 |
| Example 10 | 71000 | 15 | 11.3 | 1200 |
| Example 11 | 63000 | 15 | 10.3 | 1300 |
| Comparative | 65000 | 13 | 6.5 | 700 |
| Example 4 | | | | |

TABLE 2

| | Organic compound | | | |
|---|---|---|---|---|
| | represented by | | | |
| | Formula (1) or (3) | Eg (eV) | Ea (eV) | T1 (eV) |
| Example 6 | Compound (1) | 4.2 | 2.1 | 2.8 |
| Example 7 | Compound (4) | 4.1 | 2.1 | 2.7 |
| Example 8 | Compound (7) | 4.2 | 2.1 | 2.8 |
| Example 9 | Compound (19) | 4.1 | 2.1 | 2.7 |
| Example 10 | Compound (34) | 4.0 | 2.2 | 2.7 |
| Example 11 | Compound (44) | 4.0 | 2.3 | 2.8 |

### Example 12

1. Production of a Sample

A glass plate 2.5 cm square, and 0.5 mm in thickness, was used as a substrate, and this substrate was introduced into a vacuum chamber. An ITO target containing 10% by mass of SnO₂ (molar ratio of indium to tin=95/5) was used to form an ITO thin film (thickness: 0.2 μm) as a transparent electrode on the substrate by DC magnetron sputtering (conditions: substrate temperature of 250° C. and oxygen pressure of 1×10⁻³ Pa). The surface resistance of the ITO thin film was 10Ω/□.

Next, the substrate on which the transparent electrode was formed was put into a washing container, washed with IPA, and subjected to UV-ozone treatment for 30 minutes.

Copper phthalocyanine was deposited into a hole injecting layer 0.01 μm in thickness on this transparent electrode at a rate of 1 nm/second by vacuum vapor deposition. N,N′-dinaphthyl-N,N′-diphenylbenzidine (NPD) was deposited into a hole transporting layer 0.03 μm in thickness on the hole injecting layer at a rate of 1 nm/second by vacuum vapor deposition. A tris(2-phenylpyridyl)iridium complex (Ir(ppy)₃) as a phosphorescent light-emitting material and 4,4′-N,N′-dicarbazolebiphenyl (CBP) as a host compound were co-deposited at a vapor deposition ratio of 5/100 into a light-emitting layer 0.03 μm in thickness onto the hole transporting layer by vacuum vapor deposition.

A blocking layer was then formed on this light-emitting layer as follows. The electron transporting material used for the blocking layer was compound (59), and the organic compound represented by Formula (1) was compound (1). Compound (59) and compound (1) were co-deposited at a vapor deposition ratio of 40/60 into the blocking layer 0.01 μm in thickness by vacuum vapor deposition.

Furthermore, tris(8-hydroxyquinolinato)aluminum (Alq₃) was used as an electron transporting material to be deposited into an electron transporting layer 0.04 μm in thickness on the blocking layer at a rate of 1 nm/second by vacuum vapor deposition.

Furthermore, LiF as an electron injecting material was deposited into an electron injecting layer 0.002 μm in thickness on the electron transporting layer at a rate of 1 nm/second by vapor deposition.

Furthermore, a patterned mask (giving a light emission area of 2 mm×2 mm) was set onto this electron injecting layer, and then aluminum was vapor-deposited inside a vapor deposition machine to give a thickness of 0.25 μm. In this way, a back plate was formed.

Lead wires made of aluminum were connected to the transparent electrode (functioning as an anode) and the back plate electrode, so as to form an organic electroluminescence element.

The thus-obtained organic electroluminescence element was put into a glove box purged with nitrogen gas. In the glove box, 10 mg of calcium oxide powder as a water absorbent was put into a stainless steel sealing cover given with a concave portion at an inner side thereof, and then the cover was affixed with an adhesive tape. This sealing cover and an ultraviolet curable adhesive (XNR5516HV, manufactured by Nagase Ciba) as an adhesive were used to seal the film.

In this way, an organic semiconductor thin film of Example 12 was produced.

2. Performance Evaluation

The produced organic electroluminescence element was evaluated by the following method.

A source measure unit, 2400 model, manufactured by Toyo Technica Inc. was used to apply a DC voltage to the electroluminescence element to emit light, thereby causing this element to emit light. The initial luminescent performance of the element was then measured. The maximum luminance at this time was defined as Lmax, and the voltage at which Lmax was obtained was defined as Vmax. The light-emitting efficiency when the luminance was 2000 Cd/m² was defined as external quantum efficiency (η₂₀₀₀). The obtained results are shown in Table 3.

In a driving durability test, the organic electroluminescence element was continuously driven from an initial luminance of 1000 Cd/m², and the period when the luminance was reduced by half was obtained as the half-value period (T_{1/2}). The results are shown in Table 3.

The electrically inactive organic compounds Eg, T1, Ip were obtained by the same method as described above. The results are shown in Table 4.

### Example 13

An organic electroluminescence element was produced and then evaluated in the same manner as in Example 12 except that compound (6) was used instead of compound (1) as the organic compound represented by Formula (1) and used for the blocking layer in Example 12. The results are shown in Tables 3 and 4.

### Example 14

An organic electroluminescence element was produced and then evaluated in the same manner as in Example 12 except that compound (7) was used instead of compound (1) as the organic compound represented by Formula (1) and used for the blocking layer in Example 12. The results are shown in Tables 3 and 4.

### Example 15

An organic electroluminescence element was produced and then evaluated in the same manner as in Example 12 except that compound (19) was used instead of compound (1) as the organic compound represented by Formula (1) and used for the blocking layer in Example 12. The results are shown in Tables 3 and 4.

### Example 16

An organic electroluminescence element was produced and then evaluated in the same manner as in Example 12 except that compound (34) represented by Formula (3) was used instead of compound (1) used for the blocking layer in Example 12. The results are shown in Tables 3 and 4.

### Example 17

An organic electroluminescence element was produced and then evaluated in the same manner as in Example 12 except that compound (44) represented by Formula (3) was used instead of compound (1) used for the blocking layer in Example 12. The results are shown in Tables 3 and 4.

### Comparative Example 5

An organic electroluminescence element was produced and then evaluated in the same manner as in Example 12 except that a blocking layer made of electron transporting material (59) alone was formed without using compound (1) used for the blocking layer in Example 12. The results are shown in Table 3.

TABLE 3

| | Lmax (Cd/m²) | Vmax (V) | η max (%) | T½ (hours) |
|---|---|---|---|---|
| Example 12 | 78000 | 15 | 16.1 | 1300 |
| Example 13 | 75000 | 15 | 15.3 | 1300 |
| Example 14 | 72000 | 15 | 14.8 | 1300 |
| Example 15 | 69000 | 16 | 14.5 | 1200 |
| Example 16 | 71000 | 14 | 14.8 | 1300 |
| Example 17 | 63000 | 14 | 13.5 | 1300 |
| Comparative | 65000 | 13 | 9.7 | 450 |
| Example 5 | | | | |

TABLE 4

| | Organic compound | | | |
|---|---|---|---|---|
| | represented by | | | |
| | Formula (1) or (3) | Eg (eV) | Ip (eV) | T1 (eV) |
| Example 12 | (1) | 4.2 | 6.3 | 2.8 |
| Example 13 | (6) | 4.1 | 6.2 | 2.7 |
| Example 14 | (7) | 4.2 | 6.1 | 2.8 |
| Example 15 | (19) | 4.1 | 6.2 | 2.7 |
| Example 16 | (34) | 4.0 | 6.3 | 2.7 |
| Example 17 | (44) | 4.0 | 6.3 | 2.8 |

### Example 18

1. Production of a Sample

A glass plate 2.5 cm square, and 0.5 mm in thickness, was used as a substrate, and this substrate was introduced into a vacuum chamber. An ITO target containing 10% by mass of SnO₂ (molar ratio of indium to tin=95/5) was used to form an ITO thin film (thickness: 0.2 μm) as a transparent electrode onto the substrate by DC magnetron sputtering (conditions: a substrate temperature of 250° C. and an oxygen pressure of 1×10⁻³ Pa). The surface resistance of the ITO thin film was 10Ω/□.

Next, the substrate on which the transparent electrode was formed was put into a washing container, washed with IPA, and subjected to UV-ozone treatment for 30 minutes.

Copper phthalocyanine was deposited into a hole injecting layer 0.01 μm in thickness on this transparent electrode at a rate of 1 nm/second by vacuum vapor deposition. N,N′-dinaphthyl-N,N′-diphenylbenzidine (NPD) was deposited into a hole transporting layer 0.03 μm in thickness on the hole injecting layer at a rate of 1 nm/second by vacuum vapor deposition.

A light-emitting layer 0.03 μm in thickness was formed on this hole transporting layer by co-depositing iridium (III) bis[(4,6-di-fluorophenyl)-pyridinate-N,C]picolinate (FIrpic), which is a blue phosphorescent light-emitting material, CBP as a host material, and compound (1) as an organic compound represented by Formula (1) at a vapor co-deposition ratio by mass of 10/45/45 by vacuum vapor deposition.

A blocking layer was formed on this light-emitting layer as follows. Aluminum (III) bis(2-methyl-8-quinolinato)4-phenylphenolate (Balq₂) was used as an electron transporting material for the blocking layer to be deposited into the blocking layer 0.01 μm in thickness at a rate of 1 nm/second by vacuum vapor deposition.

Furthermore, tris(8-hydroxyquinolinato)aluminum (Alq₃) was used as an electron transporting material to be deposited into an electron transporting layer 0.04 μm in thickness on the blocking layer by vacuum vapor deposition.

Furthermore, LiF as an electron injecting material was deposited into an electron injecting layer 0.002 μm in thickness on the electron transporting layer at a rate of 1 nm/second by vapor deposition.

Furthermore, a patterned mask (giving a light emission area of 2 mm×2 mm) was set onto this electron injecting layer, and then aluminum was vapor-deposited inside a vapor deposition machine to give a thickness of 0.25 μm. In this way, a back plate was formed.

Lead wires made of aluminum were connected to the transparent electrode (functioning as an anode) and the back plate, so as to form a luminescent laminate.

The thus-obtained luminescent laminate was put into a glove box purged with nitrogen gas. In the glove box, 10 mg of calcium oxide powder as a water absorbent was put into a stainless steel sealing cover given with a concave portion at an inner side thereof, and then the cover was affixed with an adhesive tape. This sealing cover and an ultraviolet curable adhesive (XNR5516HV, manufactured by Nagase Ciba) as an adhesive were used to seal the film.

In this way, an organic electroluminescence element of Example 18 was produced.

2. Performance Evaluation

This organic luminescence element was evaluated by the following method.

A source measure unit, 2400 model, manufactured by Toyo Technica Inc. was used to apply a DC voltage to the electroluminescence element, thereby causing this element to emit light. The initial luminescent performance of the element was then measured. The maximum luminance at this time was defined as Lmax, and the voltage at which Lmax was obtained was defined as Vmax. The light-emitting efficiency when the luminance was 1000 Cd/m² was defined as external quantum efficiency (η₁₀₀₀). The obtained results are shown in Table 5

In a driving durability test, the organic electroluminescence element was continuously driven from an initial luminance of 1000 Cd/m², and the period when the luminance was reduced by half was obtained as the half-value period (T_{1/2}). The results are shown in Table 5

### Example 19

An organic electroluminescence element was produced and then evaluated in the same manner as in Example 18 except that compound (4) was used instead of compound (1) as the organic compound represented by Formula (1) and used for the light-emitting layer in Example 18. The results are shown in Table 5.

### Example 20

An organic electroluminescence element was produced and then evaluated in the same manner as in Example 18 except that compound (7) was used instead of compound (1) as the organic compound represented by Formula (1) and used for the light-emitting layer in Example 18. The results are shown in Table 5.

### Example 21

An organic electroluminescence element was produced and then evaluated in the same manner as in Example 18 except that compound (19) was used instead of compound (1) as the organic compound represented by Formula (1) and used for the light-emitting layer in Example 18. The results are shown in Table 5.

### Example 22

An organic electroluminescence element was produced and then evaluated in the same manner as in Example 18 except that compound (34) represented by Formula (3) was used instead of compound (1) used for the light-emitting layer in Example 18. The results are shown in Table 5.

### Example 23

An organic electroluminescence element was produced and then evaluated in the same manner as in Example 18 except that compound (44) represented by Formula (3) was used instead of compound (1) used for the light-emitting layer in Example 18. The results are shown in Table 5.

### Comparative Example 6

Instead of the light-emitting layer in Example 18, a light-emitting layer 0.03 μm in thickness was formed by co-depositing FIrpic as a blue phosphorescent light-emitting material and CBP as a host material at a ratio by mass of 10/90 without using compound (1) by vacuum vapor deposition.

In the same manner as in Example 18 except the above, an organic electroluminescence element was produced and evaluated. The obtained results are shown in Table 5.

TABLE 5

| | Lmax (Cd/m²) | Vmax (V) | η max (%) | T½ (hours) |
|---|---|---|---|---|
| Example 18 | 37000 | 13 | 11.5 | 1500 |
| Example 19 | 42000 | 15 | 12.1 | 1700 |
| Example 20 | 35000 | 14 | 11.3 | 1500 |
| Example 21 | 28000 | 14 | 11.2 | 1400 |
| Example 22 | 38000 | 14 | 12.0 | 1400 |
| Example 23 | 43000 | 14 | 11.5 | 1300 |
| Comparative | 15000 | 10 | 6.1 | 400 |
| Example 6 | | | | |

According to the invention, the following can be provided: an organic semiconductor thin film comprising at least one organic compound of a hole transporting material and/or an electron transporting material, wherein a localized level is not substantially present between the highest occupied molecular orbit (HOMO) and the lowest unoccupied molecular orbit (LUMO) of the film; and applications thereof (for example, an organic semiconductor element and an organic electroluminescence element). The following can also be provided: an organic semiconductor thin film comprising at least one organic compound of a hole transporting material and/or an electron transporting material, the film substantially not having any current peak observed in a temperature range of measurement temperatures of 100 to 200 K in a measurement based on a thermally stimulated current measuring method; and applications thereof (for example, an organic semiconductor element and an organic electroluminescence element).

The inventors have eagerly advanced the analysis of causes of a small response rate of any organic semiconductor element, and a dark current generated therein, so as to find out that a main cause thereof is a localized level present in the film of the organic semiconductor. The localized level is an unexpected energy level present between the highest occupied molecular orbit (HOMO) and the lowest unoccupied molecular orbit (LUMO). Hitherto, it has been known that impurities in the organic compound or reaction products produced by action of water or oxygen deteriorate the performance of the element. However, it has not necessarily been considered that the deterioration is relevant to the localized level.

Results of the analysis by the inventors have made the following evident: when this localized level is present at the time of, for example, the transfer of charges (holes or electrons), the charges are trapped into the localized level so that the localized level causes a large drop in the charge mobility; and in an organic electroluminescence element, this drop causes an unbalance between holes and electrons to cause a decrease in the light-emitting efficiency. When charges are stored in the localized level, polarization increases in the material which constitutes the organic semiconductor thin film, so that the material decomposes. The decomposition causes a fall in the lifespan of the organic electroluminescence element. This matter is also made evident.

The inventors have found out that the performance of an organic semiconductor can be drastically improved by removing any localized level thereof. Thus, the invention has been made.

The inventors have also found out that an organic semiconductor thin film substantially not having any current peak observed in the measurement of this film by the TSC method exhibits a drastically high performance. Thus, the invention has been made.

Furthermore, the inventors have found out that the incorporation of an electrically inactive aromatic compound having a specific structure into the film is unexpectedly effective as a specific means for removing any localized level.

According to the invention, an organic semiconductor thin film substantially not having any localized level between the between the highest occupied molecular orbit (HOMO) and the lowest unoccupied molecular orbit (LUMO) exhibits a very large charge mobility, and can realize significantly excellent semiconductor characteristics. An organic semiconductor element or an organic electroluminescence element comprising this organic semiconductor thin film can be effectively used for a surface light source of a full-color display, a backlight or the like, or for a light source array of a printer or the like. The invention can provide an organic electroluminescence element having a high luminance, a very high light-emitting efficiency and a significantly excellent durability.

All publications, patent applications, and technical standards mentioned in this specification are herein incorporated by reference to the same extent as if each individual publication, patent application, or technical standard was specifically and individually indicated to be incorporated by reference.

What is claimed is:

1. An organic semiconductor thin film comprising at least one organic compound of a hole transporting material and/or an electron transporting material, wherein a localized level is not substantially present between a highest occupied molecular orbit (HOMO) and a lowest unoccupied molecular orbit (LUMO) of the film.

2. An organic semiconductor thin film comprising at least one organic compound of a hole transporting material and/or an electron transporting material, the film substantially not having any current peak observed in a temperature range of measurement temperatures of 100 to 200 K in a measurement based on a thermally stimulated current measuring method.

3. The organic semiconductor thin film of claim 1, which comprises an organic compound having an energy difference (Eg) between the HOMO and the LUMO of 4.0 eV or more.

4. The organic semiconductor thin film of claim 3, wherein the organic compound is an aromatic hydrocarbon compound.

5. The organic semiconductor thin film of claim 4, wherein the aromatic hydrocarbon compound is represented by the following Formula (1):
L-(Ar)ₘ Formula (1)
wherein, in the Formula (1), Ar is a group represented by the following Formula (2), L is a phenyl group having a valence of 3 or more, and m is an integer of 3 or more: 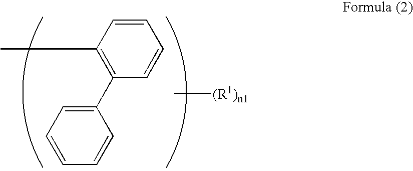
wherein R¹ is a substituent which can be substituted with a benzene ring ; when R¹ is present in plurality, each R¹ may be the same as or different from another R¹; and n1 is an integer from 0 to 9.

6. The organic semiconductor thin film of claim 5, wherein R¹ in Formula (2) comprises a substituent selected from alkyl, aryl and heteroaryl groups.

7. The organic semiconductor thin film of claim 5, wherein n1 in Formula (2) is an integer of from 0 to 6.

8. The organic semiconductor thin film of claim 4, wherein the aromatic hydrocarbon compound is represented by the following Formula (3): 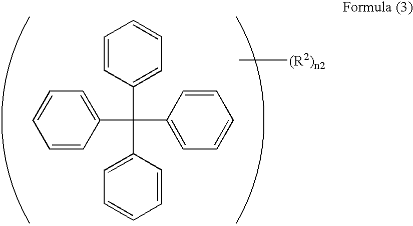
wherein R² is a substituent which can be substituted with a benzene ring; when R² is present in plurality, each R² may be the same as or different from another R²; and n2 is an integer of from 0 to 20.

9. The organic semiconductor thin film of claim 4, which comprises at least one organic compound of the hole transporting material and/or the electron transporting material, and an organic compound which has an energy difference (Eg) between the HOMO and the LUMO of 4.0 eV or more, wherein the blend ratio by mass is in the range of from 95/5 to 30/70.

10. An organic semiconductor element, comprising one or more organic semiconductor thin films between a pair of electrodes, wherein at least one of the organic semiconductor thin films is the organic semiconductor thin film of claim 1.

11. An organic semiconductor element, comprising one or more organic semiconductor thin films between a pair of electrodes, wherein at least one of the organic semiconductor thin films is the organic semiconductor thin film of claim 2.

12. An organic electroluminescence element, comprising one or more organic compound layers between a pair of electrodes, wherein at least one of the organic compound layers is the organic semiconductor thin film of claim 1.

13. An organic electroluminescence element, comprising one or more organic compound layers between a pair of electrodes, wherein at least one of the organic compound layers is the organic semiconductor thin film of claim 2.
